(19) United States
(12) Patent Application Publication
(10) Pub. No.: US 2026/0173621 A1
(43) Pub. Date: Jun. 18, 2026

(54) DISPLAY DEVICE

(71) Applicant: LG Display Co., Ltd., Seoul (KR)

(72) Inventors: YoungIn Jang, Paju-si (KR); HyeMi Lee, Seoul (KR); Soyi Lee, Paju-si (KR); Soyoung Lee, Seoul (KR)

(73) Assignee: LG Display Co., Ltd., Seoul (KR)

(21) Appl. No.: 19/334,715

(22) Filed: Sep. 19, 2025

(30) Foreign Application Priority Data
Dec. 17, 2024 (KR) 10-2024-0188392

(51) Int. Cl. H10H 29/80; H10H 29/39; H10H 29/49

(52) U.S. Cl. CPC H10H 29/842; H10H 29/39; H10H 29/49

(57) ABSTRACT

The display device includes a power line and a driving transistor, a plurality of light-emitting elements respectively including a first electrode and a second electrode, a first planarization layer partially surrounding side surfaces of the plurality of light-emitting elements, a first connection electrode disposed on the first planarization layer and configured to connect the first electrode and the driving transistor, a second connection electrode disposed on the first planarization layer, a passivation layer disposed on the first connection electrode and the second connection electrode and a second planarization layer disposed on the passivation layer and configured to partially surround the side surfaces of the plurality of light-emitting elements, wherein the passivation layer exposes an end of the first connection electrode disposed to surround a part of a side surface of one of the light-emitting element, and wherein the second planarization layer covers the end of the first connection electrode.

### CROSS-REFERENCE TO RELATED APPLICATION

This application claims the priority of Korean Patent Application No. 10-2024-0188392, filed on Dec. 17, 2024, in the Korean Intellectual Property Office, the disclosure of which is incorporated herein by reference.

### BACKGROUND

### Field

The present disclosure relates to a display device and, more particularly, to a display device that minimizes or reduces a short-circuit defect between connection electrodes.

### Description of the Related Art

As display devices used for a monitor of a computer, a TV set, a mobile phone, and the like, there are an organic light-emitting display (OLED) configured to autonomously emit, and a liquid crystal display (LCD) that requires a separate light source.

The range of applications of the display devices is diversified from the monitor of the computer and the TV set to personal mobile devices, and studies are being conducted on the display devices having wide display areas and having reduced volumes and weights.

In addition, recently, a display device including a light-emitting diode (LED) has attracted attention as a next-generation display device. Because the LED is made of an inorganic material instead of an organic material, the LED is more reliable and has a longer lifespan than a liquid crystal display device or an organic light-emitting display device. In addition, the LED may be quickly turned on or off, have excellent luminous efficiency, high impact resistance, and great stability, and display high-brightness images.

### SUMMARY

An object to be achieved by the present disclosure is to provide a display device that minimizes or reduces separation of a reflective electrode caused by moisture permeation.

Another object to be achieved by the present disclosure is to provide a display device that reduces crystallization of a reflective electrode.

Still another object to be achieved by the present disclosure is to provide a display device, in which a first connection electrode and a first electrode of a light-emitting element may be self-aligned.

Yet another object to be achieved by the present disclosure is to provide a display device, in which a third connection electrode and a second electrode of a light-emitting element may be self-aligned.

Still yet another object to be achieved by the present disclosure is to provide a display device that minimizes or reduces a short-circuit defect between connection electrodes.

An additional object to be achieved by the present disclosure is to provide a display device that reduces line resistance.

Another additional object to be achieved by the present disclosure is to provide a display device capable of detecting whether a light-emitting element is defective regardless of whether a driving transistor is defective.

Still another additional object to be achieved by the present disclosure is to provide a display device that improves electrical connection by minimizing or reducing a connection defect caused by a residual film during a process.

Objects of the present disclosure are not limited to the above-mentioned objects, and other objects, which are not mentioned above, can be clearly understood by those skilled in the art from the following descriptions.

A display device according to an example embodiment of the present disclosure includes: a substrate on which a plurality of subpixels are defined; a power line and a driving transistor disposed on the substrate; a first reflective electrode and a second reflective electrode disposed on the power line and the driving transistor and spaced apart from each other, the first reflective electrode being connected to the driving transistor, and the second reflective electrode being connected to the power line; a bonding layer disposed on the first reflective electrode and the second reflective electrode; a plurality of light-emitting elements respectively disposed in the plurality of subpixels on the bonding layer and including a first electrode and a second electrode; a first planarization layer disposed on the bonding layer and configured to partially surround side surfaces of the plurality of light-emitting elements; a first connection electrode disposed on the first planarization layer and configured to connect the first electrode and the driving transistor; a second connection electrode disposed on the first planarization layer, spaced apart from the first connection electrode, and connected to the second reflective electrode; a passivation layer disposed on the first connection electrode and the second connection electrode; a second planarization layer disposed on the passivation layer and configured to partially surround the side surfaces of the plurality of light-emitting elements; and a third connection electrode disposed on the second planarization layer and configured to connect the second electrode and the power line, wherein the passivation layer exposes an end of the first connection electrode disposed to surround a part of a side surface of a light-emitting element, among the plurality of light-emitting elements, and wherein the second planarization layer covers the end of the first connection electrode.

A display device according to another example embodiment of the present disclosure includes: a substrate on which a plurality of pixels each including a plurality of subpixels are defined; a power line and a driving transistor disposed on the substrate; a first reflective electrode and a second reflective electrode disposed on the power line and the driving transistor and spaced apart from each other, the first reflective electrode being connected to the driving transistor, and the second reflective electrode being connected to the power line; a bonding layer disposed on the first reflective electrode and the second reflective electrode; a plurality of light-emitting elements respectively disposed in the plurality of subpixels on the bonding layer and including a first electrode and a second electrode; a first planarization layer disposed on the bonding layer and configured to partially surround side surfaces of the plurality of light-emitting elements; a first connection electrode disposed on the first planarization layer and configured to connect the first electrode and the driving transistor; a second connection electrode disposed on the first planarization layer, spaced apart from the first connection electrode, and connected to the second reflective electrode; a passivation layer disposed on the first connection electrode and the second connection electrode; a second planarization layer disposed on the passivation layer and having a height that decreases toward the plurality of light-emitting elements; and a third connection electrode disposed on the second planarization layer and configured to connect the second electrode and the power line. Therefore, it is possible to minimize or reduce a short-circuit defect between the connection electrodes.

Other detailed matters of example embodiments are included in the detailed description and the drawings.

According to an example embodiment of the present disclosure, the passivation layer is disposed on the connection electrode connected to the reflective electrode, which may minimize or reduce moisture permeation into the reflective electrode.

According to an example embodiment of the present disclosure, it is possible to minimize or reduce separation of the reflective electrode caused by moisture permeation.

According to an example embodiment of the present disclosure, the display device may operate with low power consumption in terms of the reduction in production energy by minimizing or reducing a potential defect caused by corrosion of the line and improving the lifespan of the display device.

According to an example embodiment of the present disclosure, with the process of ashing the first planarization layer and the second planarization layer, the first connection electrode and the third connection electrode are connected to the light-emitting elements by the self-alignment without a separate alignment process, such that it is possible to ensure a light-emitting element transfer margin.

According to an example embodiment of the present disclosure, the passivation layer is disposed on the first connection electrode to allow the first connection electrode and the third connection electrode to be separated, which may suppress a short-circuit defect between the first connection electrode and the third connection electrode.

According to an example embodiment of the present disclosure, the second planarization layer reflows onto the portion where the first connection electrode is exposed by the passivation layer, such that the first connection electrode and the third connection electrode are separated, which may suppress a short-circuit defect in which the first connection electrode and the third connection electrode are connected.

According to an example embodiment of the present disclosure, the illumination inspection signal is applied to the light-emitting element without passing through the driving transistor, which may detect whether the light-emitting element is defective regardless of whether the driving transistor is defective.

The effects according to the present disclosure are not limited to the contents exemplified above, and various additional effects are included in the present disclosure.

Additional features and aspects of the present disclosure are set forth in the description that follows and in part will become apparent from the description or may be learned by practice of the inventive concepts provided herein. Other features and aspects of the inventive concepts may be realized and attained by the structure particularly pointed out in, or derivable from, the written description, claims hereof, and the appended drawings.

It is to be understood that both the foregoing general description and the following detailed description of the present disclosure are by way of example and are intended to provide further explanation of the disclosures as claimed.

### BRIEF DESCRIPTION OF DRAWINGS

The accompanying drawings, which are included to provide a further understanding of the present disclosure and are incorporated in and constitute a part of this application, illustrate various aspects of the present disclosure and together with the description serve to explain various principles of the present disclosure. In the drawings:

FIG. 1 is a schematic configuration view of a display device according to an example embodiment of the present disclosure;

FIG. 2 is an enlarged top plan view of a pixel of the display device according to an example embodiment of the present disclosure;

FIG. 3 is a cross-sectional view taken along line III-III′ in FIG. 2; and

FIGS. 4A to 4H are process diagrams of a method of manufacturing the display device according to an example embodiment of the present disclosure.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various other forms. The below example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with a more limiting term like “only”. Any references to singular may include plural, and vice versa, unless expressly stated otherwise.

Components are to be interpreted to include an ordinary error range even if not expressly stated.

Where the position relation between two parts is described using the terms such as “on”, “above”, “below”, and “next”, one or more parts may be positioned between the two parts unless the terms are used with a more limiting term like “immediately” or “directly”.

Where an element or layer is described as being disposed “on” another element or layer, another layer or another element may be interposed directly on the other element or therebetween.

Although the terms “first”, “second”, and the like may be used for describing various components, these components are not confined by these terms. These terms are merely used for referring to one component separately from the other components. Therefore, a first component to be mentioned below may be a second component, and vice versa, in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings.

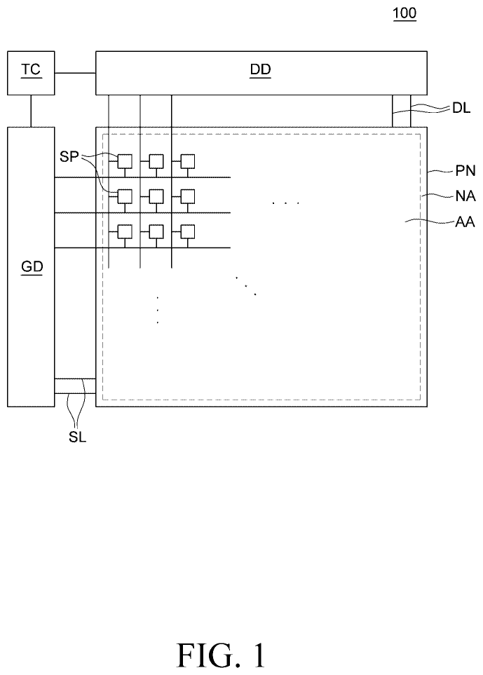

FIG. 1 is a schematic configuration view of a display device according to an example embodiment of the present disclosure. For convenience of description, FIG. 1 illustrates only a display panel PN, a gate driver GD, a data driver DD, and a timing controller TC among various constituent elements of a display device 100.

With reference to FIG. 1, the display device 100 includes the display panel PN including a plurality of subpixels SP, the gate driver GD configured to supply various types of signals to the display panel PN, and the timing controller TC configured to control the data driver DD, the gate driver GD, and the data driver DD.

The gate driver GD supplies a plurality of scan signals to a plurality of scan lines SL in response to a plurality of gate control signals provided from the timing controller TC. FIG. 1 illustrates that the single gate driver GD is disposed to be spaced apart from one side of the display panel PN. However, the number and arrangement of the gate driver GD are not limited thereto.

The data driver DD converts image data, which is inputted from the timing controller TC, into a data voltage by using a reference gamma voltage in response to a plurality of data control signals provided from the timing controller TC. The data driver DD may supply the converted data voltage to a plurality of data lines DL.

The timing controller TC aligns image data, which is inputted from the outside, and supplies the image data to the data driver DD. The timing controller TC may generate the gate control signals and the data control signals by using synchronizing signals, i.e., dot clock signals, data enable signals, and horizontal/vertical synchronizing signals inputted from the outside. Further, the timing controller TC may control the gate driver GD and the data driver DD by supplying the generated gate control signals and data control signals to the gate driver GD and the data driver DD.

The display panel PN is configured to display images to a user and includes the plurality of subpixels SP. In the display panel PN, a plurality of scan lines SL and a plurality of data lines DL intersect one another, and each of the plurality of subpixels SP is connected to the scan line SL and the data line DL. In addition, although not illustrated in the drawings, the plurality of subpixels SP may be respectively connected to a high-potential power line, a low-potential power line, a reference line, and the like.

The display panel PN may have a display area AA, and a non-display area NA configured to surround the display area AA.

The display area AA is an area of the display device 100 in which images are displayed. The display area AA may include the plurality of subpixels SP constituting a plurality of pixels PX, and a circuit configured to operate the plurality of subpixels SP. The plurality of subpixels SP are minimum units that constitute the display area AA. The n subpixels SP may constitute one pixel PX. A light-emitting element, a thin-film transistor for operating the light-emitting element, and the like may be disposed in each of the plurality of subpixels SP. The plurality of light-emitting elements may be differently defined depending on the type of the display panel PN. For example, in case that the display panel PN is an inorganic light-emitting display panel, the light-emitting element may be a light-emitting diode (LED) or a micro light-emitting diode (micro LED).

A plurality of signal lines for transmitting various types of signals to the plurality of subpixels SP are disposed in the display area AA. For example, the plurality of signal lines may include the plurality of data lines DL for supplying data voltages to the plurality of subpixels SP, and the plurality of scan lines SL for supplying gate voltages to the plurality of subpixels SP. The plurality of scan lines SL may extend in one direction in the display area AA and be connected to the plurality of subpixels SP. The plurality of data lines DL may extend in a direction different from one direction in the display area AA and be connected to the plurality of subpixels SP. In addition, a low-potential power line, a high-potential power line, and the like may be further disposed in the display area AA. However, the present disclosure is not limited thereto.

The non-display area NA may be defined as an area in which no image is displayed, i.e., an area extending from the display area AA. The non-display area NA may include link lines and pad electrodes for transmitting signals to the subpixels SP in the display area AA. Alternatively, the non-display area NA may include drive ICs such as gate driver ICs and data driver ICs. The non-display area NA may be positioned on a rear surface of the display panel PN, i.e., a surface on which the subpixel SP is not present. Alternatively, the non-display area NA may be excluded. However, the present disclosure is not limited to the configuration illustrated in the drawings.

Meanwhile, the drivers such as the gate driver GD, the data driver DD, and the timing controller TC may be connected to the display panel PN in various ways. For example, the gate driver GD may be mounted in a non-display area NA by a gate-in-panel (GIP) method or mounted between the plurality of subpixels SP by a gate-in-active area (GIA) method in a display area AA. For example, the data driver DD and the timing controller TC may be formed on a separate flexible film and a printed circuit board and electrically connected to the display panel PN by a method of bonding the flexible film and the printed circuit board to a pad electrode formed in the non-display area NA of the display panel PN. In case that the gate driver GD is mounted by the GIP method and the data driver DD and the timing controller TC transmit signals to the display panel PN through the pad electrode in the non-display area NA, ensuring an area of the non-display area NA to dispose the gate driver GD and the pad electrode may increase a size of the bezel.

Alternatively, in case that the gate driver GD is mounted in the display area AA by the GIA method and a side line, which connects a signal line on a front surface of the display panel PN to the pad electrode on the rear surface of the display panel PN, is formed to bond the flexible film and the printed circuit board to the rear surface of the display panel PN, it is possible to minimize or reduce the non-display area NA on the front surface of the display panel PN. That is, in case that the gate driver GD, the data driver DD, and the timing controller TC are connected to the display panel PN by the above-mentioned method, a zero bezel in which the bezel is not substantially present may be implemented.

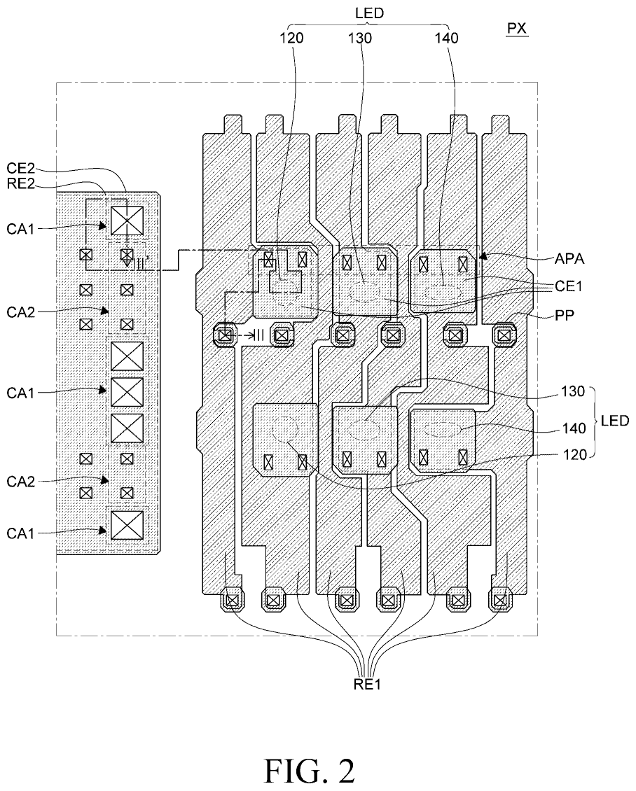

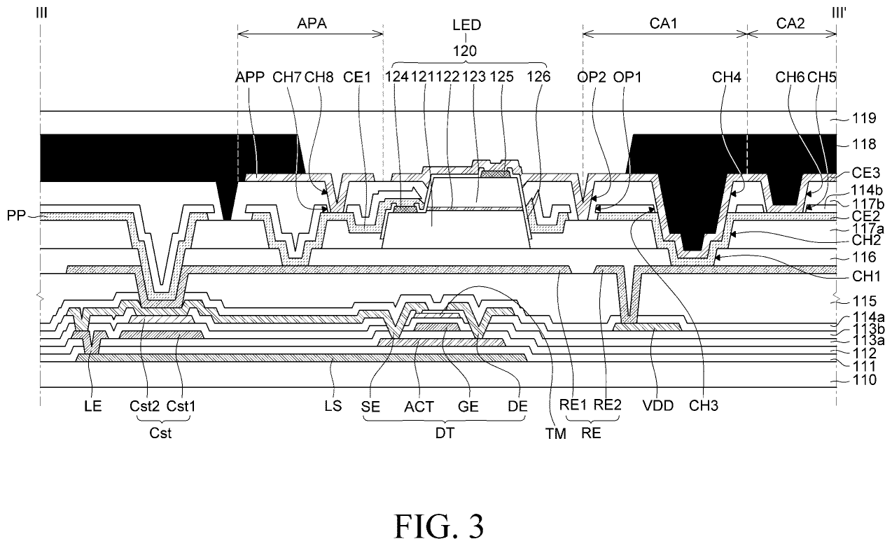

FIG. 2 is an enlarged top plan view of the pixel of the display device according to an example embodiment of the present disclosure. FIG. 3 is a cross-sectional view taken along line III-III′ in FIG. 2. FIG. 2 illustrates only a first reflective electrode RE1, a second reflective electrode RE1, a first connection electrode CE1, a second connection electrode CE2, and a light-emitting element LED among the components of the display device 100. FIG. 3 is a cross-sectional view illustrating a first subpixel including a first light-emitting element 120. The cross-section of the first subpixel including the first light-emitting element 120 is identical to a cross-section of a second subpixel including a second light-emitting element 130 and a cross-section of a third subpixel including a third light-emitting element 140.

First, with reference to FIGS. 1 and 3, the display panel PN includes the plurality of pixels PX each having the plurality of subpixels SP. The plurality of subpixels SP may each include the light-emitting element LED and a pixel circuit and independently emit light. One pixel PX may include a first subpixel, a second subpixel, and a third subpixel. For example, one pixel PX may include one first subpixel, one second subpixel, and one third subpixel. In this case, the first subpixel may be a red subpixel, the second subpixel may be a green subpixel, and the third subpixel may be a blue subpixel. However, the present disclosure is not limited thereto.

The plurality of light-emitting elements LED may be respectively disposed in the plurality of subpixels SP. Specifically, the plurality of light-emitting elements LED include the first light-emitting element 120, the second light-emitting element 130, and the third light-emitting element 140. The first light-emitting element 120 may be disposed in the first subpixel, the second light-emitting element 130 may be disposed in the second subpixel, and the third light-emitting element 140 may be disposed in the third subpixel. For example, the first light-emitting element 120 may be a red light-emitting element, the second light-emitting element 130 may be a green light-emitting element, and the third light-emitting element 140 may be a blue light-emitting element.

Meanwhile, with reference to FIG. 2, the first light-emitting element 120, the second light-emitting element 130, and the third light-emitting element 140 may have different shapes. For example, a planar shape of the first light-emitting element 120 may be a circular shape, and a planar shape of each of the second light-emitting element 130 and the third light-emitting element 140 may be an elliptical shape. In this case, the second light-emitting element 130 and the third light-emitting element 140 may be different in sizes and thus have different elliptical shapes. Meanwhile, the second light-emitting element 130 and the third light-emitting element 140 may be identical in major axis directions. However, the present disclosure is not limited thereto.

With reference to FIG. 3 together, the first light-emitting element 120 may include a first semiconductor layer 121, a light-emitting layer 122, a second semiconductor layer 123, a first electrode 124, a second electrode 125, and a passivation film 126. Meanwhile, although not illustrated in the drawings, a planar shape of the first semiconductor layer 121 of the first light-emitting element 120 may be a circular shape, and a planar shape of the second semiconductor layer 123 may be a semicircular shape. A planar shape of the first electrode 124 may be an elliptical shape. The second electrode 125 may have a semicircular shape, like a top surface of the second semiconductor layer 123.

The second light-emitting element 130 may include a first semiconductor layer, a light-emitting layer, a second semiconductor layer, a first electrode, a second electrode, and a passivation film. Meanwhile, although not illustrated in the drawings, planar shapes of the first semiconductor layer and the first electrode of the second light-emitting element 130 may be elliptical shapes. In this case, a major axis direction of the first semiconductor layer may be configured to be different from a major axis direction of the first electrode. For example, when the first semiconductor layer has an elliptical shape having a major axis in a horizontal direction, the first electrode may have an elliptical shape having a major axis in a vertical direction. For example, the first electrode may be disposed on a top surface of the first semiconductor layer and disposed at one end of the first semiconductor layer based on the major axis direction. A planar shape of each of the second semiconductor layer and the second electrode may be a cut-out elliptical shape.

The third light-emitting element 140 may include a first semiconductor layer, a light-emitting layer, a second semiconductor layer, a first electrode, a second electrode, and a passivation film. Meanwhile, although not illustrated in the drawings, planar shapes of the first semiconductor layer and the first electrode of the third light-emitting element 140 may be elliptical shapes. Unlike the second light-emitting element, the major axis direction of the first semiconductor layer may be identical to the major axis direction of the first electrode in the third light-emitting element 140. For example, the first electrode may be disposed on a top surface of the first semiconductor layer and disposed at one end of the first semiconductor layer based on the major axis direction. A planar shape of each of the second semiconductor layer and the second electrode may be a cut-out elliptical shape.

That is, in the display device 100 according to the embodiment of the present disclosure, the first light-emitting element 120, the second light-emitting element 130, and the third light-emitting element 140 may have different shapes, such that the plurality of light-emitting elements LED may be distinguished. For example, during a process of self-assembling the light-emitting elements LED, the plurality of light-emitting elements LED may be formed in different shapes, such that the plurality of light-emitting elements LED may be self-assembled at positions respectively corresponding to the plurality of subpixels SP. However, the shapes of the plurality of light-emitting elements LED are examples, and the present disclosure is not limited thereto.

Meanwhile, with reference to FIG. 2, a first contact area CA1, a second contact area CA2, and an illumination inspection area APA may be defined in each of the plurality of pixels PX of the display panel PN of the display device 100 according to the embodiment of the present disclosure.

The first contact area CA1 and the second contact area CA2 may be areas in which a power line VDD and a third connection electrode CE3 are electrically connected. For example, in the first contact area CA1, the third connection electrode CE3 may be electrically connected to the power line through a second reflective electrode RE2 and the second connection electrode CE2. In the second contact area CA2, the third connection electrode CE3 extending from the first contact area CA1 may be additionally connected to the second connection electrode CE2 extending from the first contact area CA1, such that the third connection electrode CE3 may be electrically connected to the power line.

The illumination inspection area APA may be an area that transmits an illumination inspection signal to detect whether the light-emitting element LED is defective. For example, in the illumination inspection area APA, an illumination inspection pattern may transmit illumination inspection signals to first electrodes of the light-emitting element LED through the first connection electrode CE1 without passing through a driving transistor DT. Therefore, it is possible to detect whether the light-emitting element LED is defective regardless of a defect of the driving transistor DT. The details related to the above-mentioned configuration will be described with reference to FIG. 3 to be described below.

Next, with reference to FIG. 3 together, a substrate 110, a buffer layer 111, a gate insulation layer 112, a first interlayer insulation layer 113a, a second interlayer insulation layer 113b, a first passivation layer 114a, a second passivation layer 114b, an overcoating layer 115, a bonding layer 116, a first planarization layer 117a, a second planarization layer 117b, a bank 118, a third planarization layer 119, the driving transistor DT, the light-emitting element LED, a reflective electrode RE, a light-blocking layer LS, an auxiliary electrode LE, the first connection electrode CE1, the second connection electrode CE2, the third connection electrode CE3, a capacitor Cst, an intermediate electrode TM, and an illumination inspection pattern APP may be disposed in each of the plurality of subpixels SP on the display panel PN of the display device 100 according to the embodiment of the present disclosure.

First, the substrate 110 is a component for supporting various constituent elements included in the display device 100 and may be made of an insulating material. For example, the substrate 110 may be made of glass, resin, or the like. In addition, the substrate 110 may include plastic such as polymer and may be made of a material having flexibility.

The light-blocking layer LS may be disposed in each of the plurality of subpixels SP on the substrate 110. The light-blocking layer LS blocks light entering an active layer ACT of the driving transistor DT, which will be described below, from a lower side of the substrate 110. The light-blocking layer LS may block light entering the active layer ACT of the driving transistor DT, thereby minimizing or reducing a leakage current.

The buffer layer 111 may be disposed on the substrate 110 and the light-blocking layer LS. The buffer layer 111 may reduce the penetration of moisture or impurities through the substrate 110. For example, the buffer layer 111 may be configured as a single layer or multilayer made of silicon oxide (SiOₓ) or silicon nitride (SiNₓ). However, the present disclosure is not limited thereto. However, the buffer layer 111 may be excluded in accordance with the type of substrate 110 or the type of transistor. However, the present disclosure is not limited thereto.

The driving transistor DT may be disposed on the buffer layer 111. The driving transistor DT includes the active layer ACT, a gate electrode GE, a source electrode SE, and a drain electrode DE.

The active layer ACT may be disposed on the buffer layer 111. The active layer ACT may be made of a semiconductor material such as an oxide semiconductor, amorphous silicon, or polysilicon. However, the present disclosure is not limited thereto.

The gate insulation layer 112 may be disposed on the active layer ACT. The gate insulation layer 112 is an insulation layer for insulating the active layer ACT and the gate electrode GE. The gate insulation layer 112 may be configured as a single layer or multilayer made of silicon oxide (SiOₓ) or silicon nitride (SiNₓ). However, the present disclosure is not limited thereto.

The gate electrode GE may be disposed on the gate insulation layer 112. The gate electrode GE may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The first interlayer insulation layer 113a and the second interlayer insulation layer 113b may be disposed on the gate electrode GE. Contact holes, through which the source electrode SE and the drain electrode DE are connected to the active layer ACT, are formed in the gate insulation layer 112, the first interlayer insulation layer 113a, and the second interlayer insulation layer 113b. The first interlayer insulation layer 113a and the second interlayer insulation layer 113b may be insulation layers for protecting components disposed below the first interlayer insulation layer 113a and the second interlayer insulation layer 113b and each configured as a single layer or multilayer made of silicon oxide (SiOₓ) or silicon nitride (SiNₓ). However, the present disclosure is not limited thereto.

The source electrode SE and the drain electrode DE, which are electrically connected to the active layer ACT, may be disposed on the second interlayer insulation layer 113b. The source electrode SE and the drain electrode DE may each be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

Meanwhile, in the present disclosure, the configuration has been described in which the first interlayer insulation layer 113a and the second interlayer insulation layer 113b, i.e., the plurality of insulation layers is disposed between the gate electrode GE, the source electrode SE, and the drain electrode DE. However, only a single insulation layer may be disposed between the gate electrode GE, the source electrode SE, and the drain electrode DE. However, the present disclosure is not limited thereto.

In addition, although not illustrated in the drawings, the pixel circuit may further include a switching transistor, a sensing transistor, a light emission control transistor, and the like in addition to the driving transistor DT. However, the present disclosure is not limited thereto.

Meanwhile, the intermediate electrode TM may be disposed on the first interlayer insulation layer 113a. The intermediate electrode TM may be disposed to overlap the gate electrode GE of the driving transistor DT with the first interlayer insulation layer 113a interposed therebetween and constitute a capacitor together with the gate electrode GE of the driving transistor DT. However, the present disclosure is not limited thereto.

The auxiliary electrode LE may be disposed on the gate insulation layer 112. The auxiliary electrode LE is an electrode configured to electrically connect the light-blocking layer LS, which is disposed below the buffer layer 111, to any one of the source electrode SE of the driving transistor DT and the drain electrode DE of the driving transistor DT on the second interlayer insulation layer 113b. For example, the light-blocking layer LS may be electrically connected to any one of the source electrode SE and the drain electrode DE of the driving transistor DT through the auxiliary electrode LE so as not to be operated as a floating gate, thereby minimizing or reducing a change in threshold voltage of the driving transistor DT caused by the floating light-blocking layer LS. The drawing illustrates that the light-blocking layer LS is connected to the source electrode SE of the driving transistor DT. However, the light-blocking layer LS may be connected to the drain electrode DE of the driving transistor DT. However, the present disclosure is not limited thereto.

The capacitor Cst may be disposed on the gate insulation layer 112. The capacitor Cst may include a first capacitor electrode Cst1 and a second capacitor electrode Cst2.

First, the first capacitor electrode Cst1 may be disposed on the gate insulation layer 112. The first capacitor electrode Cst1 may be disposed on the same layer and made of the same material as the gate electrode GE. However, the present disclosure is not limited thereto.

The second capacitor electrode Cst2 may be disposed on the first interlayer insulation layer 113a. The second capacitor electrode Cst2 may be disposed on the same layer and made of the same material as the intermediate electrode TM. However, the present disclosure is not limited thereto. The second capacitor electrode Cst2 may be disposed to overlap the first capacitor electrode Cst1 with the first interlayer insulation layer 113a interposed therebetween. The second capacitor electrode Cst2 may be connected to the source electrode SE of the driving transistor DT.

The power line VDD may be disposed on the second interlayer insulation layer 113b. The power line VDD may be electrically connected to the light-emitting element LED together with the driving transistor DT and allow the light-emitting element LED to emit light. The power line VDD may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The first passivation layer 114a may be disposed on the driving transistor DT and the power line VDD. The first passivation layer 114a may protect the driving transistor DT and the power line VDD from the permeation of moisture or impurities. For example, the first passivation layer 114a may be configured as a single layer or multilayer made of silicon oxide (SiOₓ) or silicon nitride (SiNₓ). However, the present disclosure is not limited thereto. However, the first passivation layer 114a may be excluded in accordance with the type of substrate 110 or the type of transistor. However, the present disclosure is not limited thereto.

The overcoating layer 115 may be disposed on the first passivation layer 114a. The overcoating layer 115 may planarize an upper portion of the substrate 110 on which the driving transistor DT is disposed. The overcoating layer 115 may be configured as a single layer or multilayer and made of a photoresist or an acrylic-based organic material, for example. However, the present disclosure is not limited thereto.

The plurality of reflective electrodes RE, which are spaced apart from one another, may be disposed on the overcoating layer 115. The plurality of reflective electrodes RE may serve to electrically connect the light-emitting element LED to the power line VDD and the driving transistor DT and serve as a reflective plate that reflects light, which is emitted from the light-emitting element LED, to the upper portion of the light-emitting element LED. The plurality of reflective electrodes RE may each be made of an electrically conductive material having excellent reflection performance and reflect the light, which is emitted from the light-emitting element LED, toward the upper portion of the light-emitting element LED. Therefore, the plurality of reflective electrodes RE may include various conductive layers in consideration of light reflection efficiency and resistance. For example, the reflective plate may be made by using an opaque conductive layer, which is made of silver (Ag), aluminum (Al), molybdenum (Mo), titanium (Ti), or an alloy thereof, together with a transparent conductive layer made of indium tin oxide (ITO). However, the structure and material of the reflective plate RE are not limited thereto.

The plurality of reflective electrodes RE may include the first reflective electrode RE1 and the second reflective electrode RE2. The first reflective electrode RE1 may electrically connect the driving transistor DT and the light-emitting element LED. The first reflective electrode RE1 may be connected to the source electrode SE or the drain electrode DE of the driving transistor DT through contact holes formed in the first passivation layer 114a and the overcoating layer 115. Further, the first reflective electrode RE1 may be electrically connected to the first electrode 124 of the light-emitting element LED through the first connection electrode CE1.

The second reflective electrode RE2 may electrically connect the power line VDD and the light-emitting element LED. The second reflective electrode RE2 may be connected to the power line VDD through contact holes formed in the first passivation layer 114a and the overcoating layer 115 and electrically connected to the second electrode 125 of the light-emitting element LED through the second connection electrode CE2 and the third connection electrode CE3 to be described below.

On the plurality of reflective electrodes RE, the bonding layer 116 may be formed on the front surface of the substrate 110 and fix the light-emitting element LED disposed on the bonding layer 116. The bonding layer 116 may be made of a photocurable or thermosetting bonding material that may be cured by light or heat. For example, the bonding layer 116 may be made of an acrylic-based material including a photosensitive agent. However, the present disclosure is not limited thereto.

The plurality of light-emitting elements LED may be provided on the bonding layer 116 and disposed in each of the plurality of subpixels SP. The plurality of light-emitting elements LED may be elements configured to emit light by using an electric current and include the light-emitting elements LED configured to emit red light, green light, blue light, and the like. The plurality of light-emitting elements LED may implement light with various colors including white by using a combination of red light, green light, blue light, and the like. For example, the plurality of light-emitting elements LED may each be a light-emitting diode (LED) or a micro LED. However, the present disclosure is not limited thereto.

The first light-emitting element 120 may include the first semiconductor layer 121, the light-emitting layer 122, the second semiconductor layer 123, the first electrode 124, the second electrode 125, and the passivation film 126.

The first semiconductor layer 121 may be disposed on the bonding layer 116, and the second semiconductor layer 123 may be disposed on the first semiconductor layer 121. The first semiconductor layer 121 and the second semiconductor layer 123 may each be a layer formed by doping a particular material with n-type and p-type impurities. For example, the first semiconductor layer 121 and the second semiconductor layer 123 may each be a layer formed by doping a material, such as gallium nitride (GaN), indium aluminum phosphide (InAlP), or gallium arsenide (GaAs) with n-type and p-type impurities. Further, the p-type impurity may be magnesium, zinc (Zn), beryllium (Be), or the like. The n-type impurity may be silicon (Si), germanium, tin (Sn), or the like. However, the present disclosure is not limited thereto.

A part of the first semiconductor layer 121 may be disposed to protrude to the outside of the second semiconductor layer 123. The top surface of the first semiconductor layer 121 may include a portion, which overlaps a bottom surface of the second semiconductor layer 123, and a portion disposed outside a bottom surface of the second semiconductor layer 123. The light-emitting element LED may be a lateral light-emitting element LED. However, the first semiconductor layer 121 and the second semiconductor layer 123 may be variously modified in sizes and shapes. However, the present disclosure is not limited thereto.

For example, the first semiconductor layer 121 may protrude to the outside of the second semiconductor layer 123 in one direction. The first semiconductor layer 121 may protrude to the outside of the second semiconductor layer 123 at an edge of a part of the second semiconductor layer 123. A part of the first semiconductor layer 121 may protrude to the outside of the second semiconductor layer 123 in a particular direction.

The light-emitting layer 122 may be disposed between the first semiconductor layer 121 and the second semiconductor layer 123. The light-emitting layer 122 may emit light by receiving positive holes and electrons from the first semiconductor layer 121 and the second semiconductor layer 123.

The light-emitting layer 122 may be configured as a single layer or a multi-quantum well (MQW) structure. For example, the light-emitting layer 122 may be made of indium gallium nitride (InGaN), gallium nitride (GaN), or the like. However, the present disclosure is not limited thereto.

The first electrode 124 may be disposed on the first semiconductor layer 121. The first electrode 124 is an electrode that electrically connects the driving transistor DT and the first semiconductor layer 121. In this case, the first semiconductor layer 121 may be a semiconductor layer doped with n-type impurities, and the first electrode 124 may be a cathode. The first electrode 124 may be disposed on the top surface of the first semiconductor layer 121 exposed from the light-emitting layer 122 and the second semiconductor layer 123. For example, the first electrode 124 may be disposed around the top surface of the first semiconductor layer 121, and a planar shape of the first electrode 124 may be a ring shape. The first electrode 124 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The second electrode 125 may be disposed on the second semiconductor layer 123. The second electrode 125 may be disposed on a top surface of the second semiconductor layer 123. In this case, because the second semiconductor layer 123 is disposed on the first semiconductor layer 121, the second electrode 125, which is disposed on the top surface of the second semiconductor layer 123, may be disposed at a position higher than the first electrode 124 disposed on the top surface of the first semiconductor layer 121. The second electrode 125 is an electrode for electrically connecting the power line VDD and the second semiconductor layer 123. In this case, the second semiconductor layer 123 may be a semiconductor layer doped with p-type impurities, and the second electrode 125 may be an anode. The second electrode 125 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

Next, the passivation film 126 may be disposed to surround the first semiconductor layer 121, the light-emitting layer 122, the second semiconductor layer 123, the first electrode 124, and the second electrode 125. The passivation film 126 may be made of an insulating material and protect the first semiconductor layer 121, the light-emitting layer 122, and the second semiconductor layer 123. Further, a contact hole, through which the first electrode 124 and the second electrode 125 are exposed, may be formed in the passivation film 126, such that the first connection electrode CE1, the third connection electrode CE3, the first electrode 124, and the second electrode 125, which are formed subsequently, may be electrically connected.

Meanwhile, although not illustrated in FIG. 3, the second light-emitting element 130 and the third light-emitting element 140 may be disposed in substantially the same manner as the first light-emitting element 120.

The first planarization layer 117a may be disposed on the bonding layer 116. The first planarization layer 117a may be disposed to partially surround side surfaces of the plurality of light-emitting elements LED and fix and protect the plurality of light-emitting elements LED.

For example, the first planarization layer 117a may be disposed to surround the passivation film 126 disposed at a lower edge of the light-emitting element LED. Therefore, it is possible to suppress the disconnection of the first connection electrode CE1 caused by tearing of the passivation film 126. For example, a part of the passivation film 126 may be torn from the lower edge of the light-emitting element LED during a process of separating the light-emitting element LED from a wafer. Therefore, the passivation film 126 may expose a part of the first semiconductor layer 121 at the lower edge of the light-emitting element LED. Therefore, a level difference may occur at the lower edge of the light-emitting element LED because of tearing of the passivation film 126. In this case, in case that the first connection electrode CE1 is disposed to surround the side surface of the passivation film 126, the first connection electrode CE1 may be disconnected by the level difference caused by tearing of the passivation film 126.

Therefore, the first planarization layer 117a is disposed to surround the lower edge of the light-emitting element LED before the first connection electrode CE1 is disposed, such that the lower edge of the light-emitting element LED and the first connection electrode CE1 may be spaced apart from each other. Therefore, even though an undercut structure is formed at the lower edge of the light-emitting element LED because of the tearing of the passivation film 126, the first planarization layer 117a fills the undercut structure while contacting at least a part of the side surface of the light-emitting element LED, which may minimize or reduce the disconnection of the first connection electrode CE1 caused by the undercut structure.

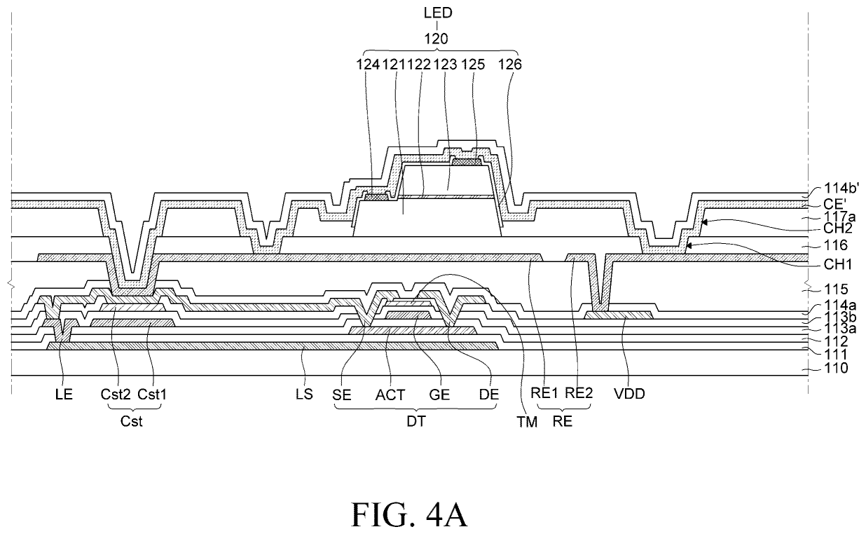

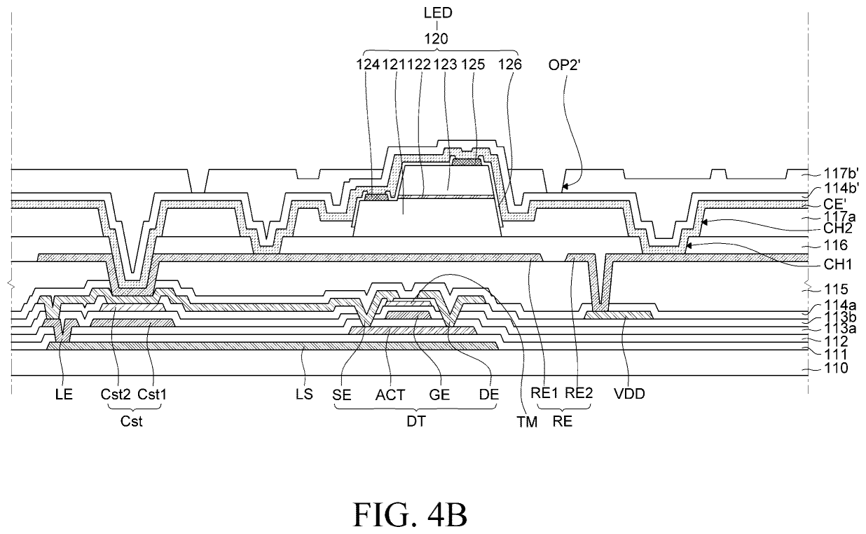

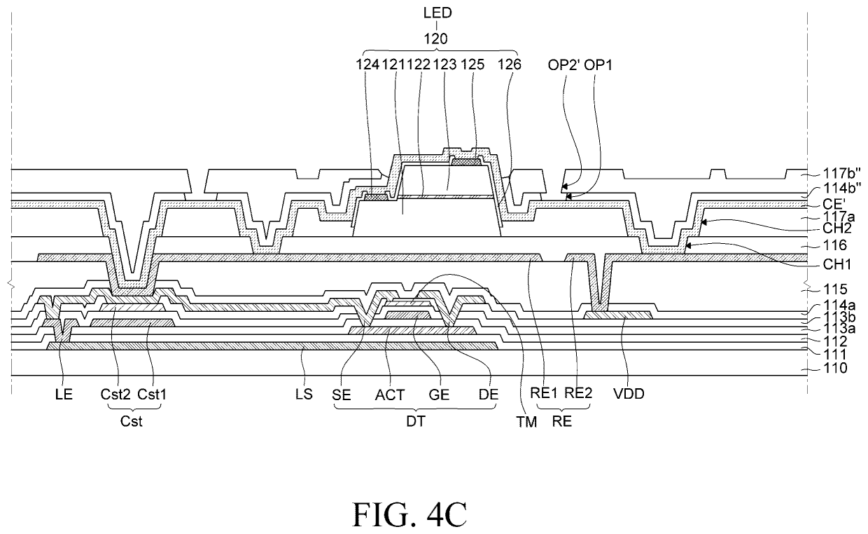

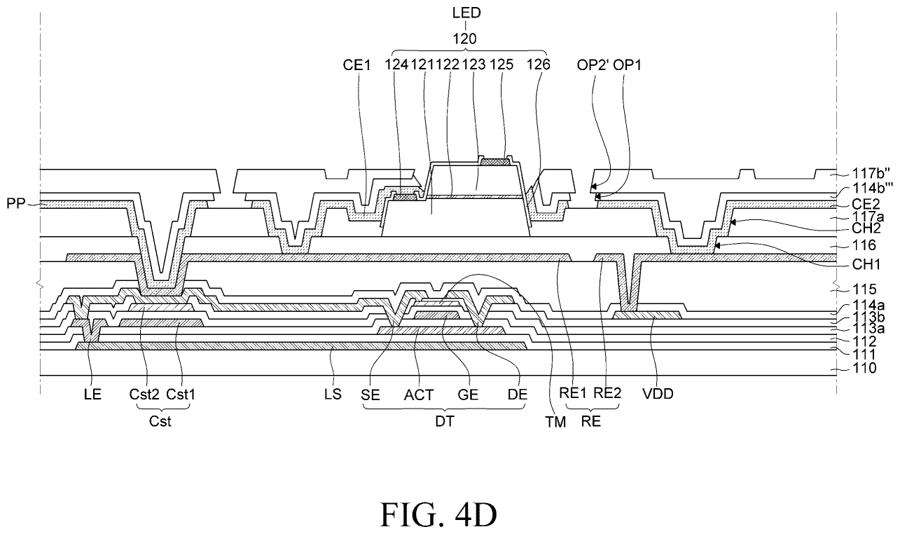

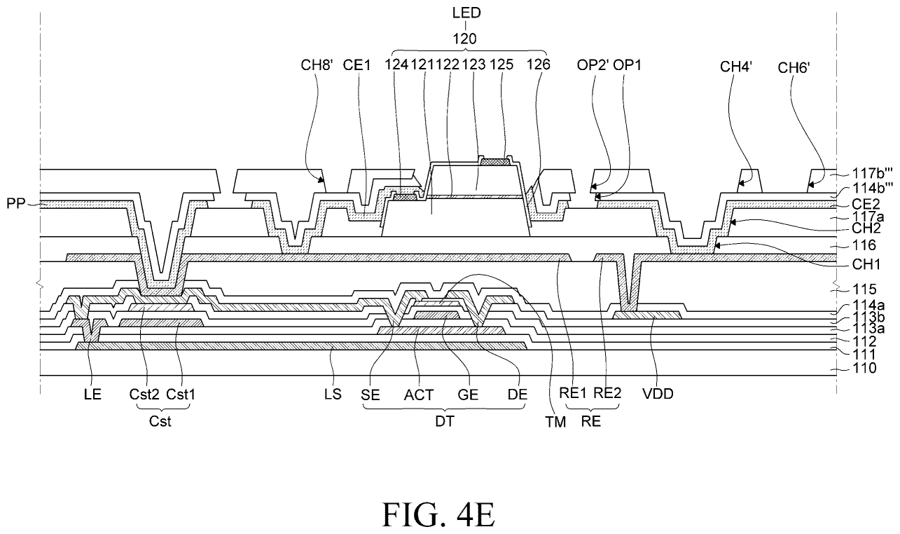

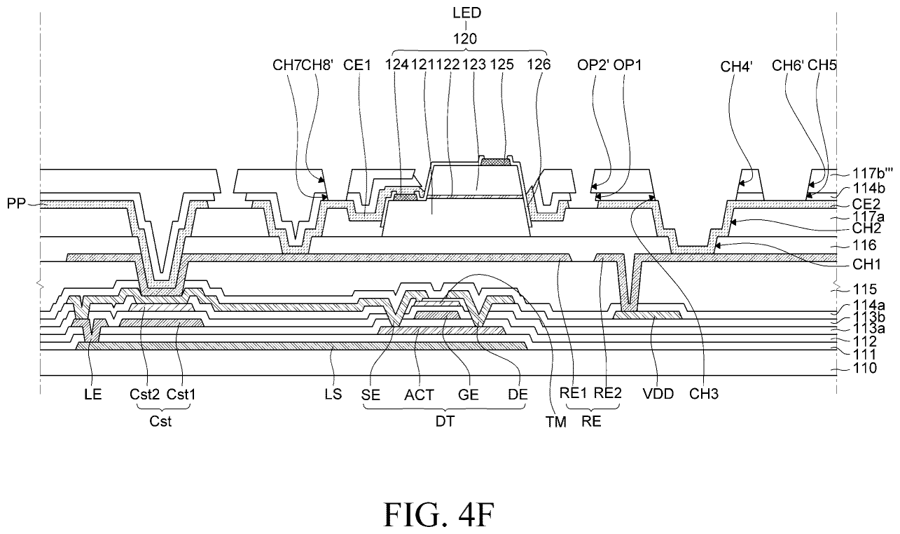

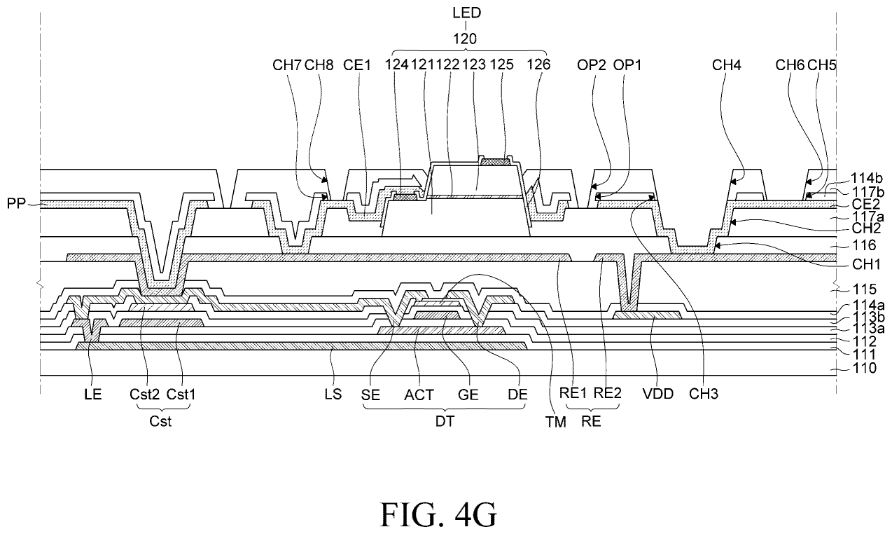

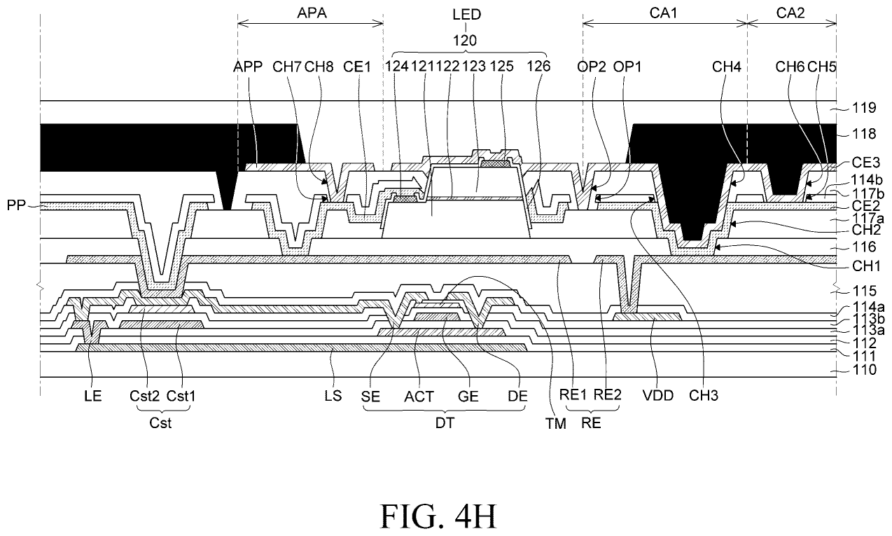

Meanwhile, the first planarization layer 117a may be disposed to be lower than a height of the first electrode 124 and expose the first electrode 124. Therefore, the first connection electrode CE1 disposed on the first planarization layer 117a may be easily connected to the first electrode 124. The details related to the above-mentioned configuration will be described in detail with reference to FIGS. 4A to 4H to be described below.

In addition, the first planarization layer 117a may include a portion that is relatively low in height in an area adjacent to the light-emitting element LED. For example, the portion relatively low in height may be included by removing a part of the first planarization layer 117a in the area adjacent to the light-emitting element LED during a process of forming the contact hole of the passivation film 126 to expose the first electrode 124 and the second electrode 125. The details related to the above-mentioned configuration will be described in detail with reference to FIGS. 4A to 4H to be described below.

The first planarization layer 117a may be configured as a single layer or multilayer and made of a photoresist or an acrylic-based organic material, for example. However, the present disclosure is not limited thereto.

Meanwhile, the first planarization layer 117a may be lower than the height of the first electrode 124. For example, a thickness of the first planarization layer 117a may be adjusted by performing an ashing process. For example, after a material layer of the first planarization layer 117a is applied to cover the light-emitting element LED, the ashing process is performed to decrease an overall thickness of the material layer of the first planarization layer 117a, such that a height of the first planarization layer 117a may be lower than the height of the first electrode 124. Therefore, the first planarization layer 117a may expose the first electrode 124. Therefore, the first connection electrode CE1 disposed on the first planarization layer 117a may be easily connected to the first electrode 124 without a separate contact hole. Therefore, the first connection electrode CE3 and the first electrode 124 may be self-aligned without having to ensure a process margin.

The first connection electrode CE1 may be disposed on the first planarization layer 117a. The first connection electrode CE1 is an electrode disposed in each of the plurality of subpixels SP and configured to electrically connect the light-emitting element LED and the driving transistor DT. The first connection electrode CE1 may be disposed in a shape that surrounds the light-emitting element LED. The first connection electrode CE1 may be connected to the first reflective electrode RE1 through contact holes formed in the first planarization layer 117a and the bonding layer 116. Therefore, the first connection electrode CE1 may be electrically connected to any one of the source electrode SE and the drain electrode DE of the driving transistor DT through the first reflective electrode RE1. For example, the first connection electrode CE1 may connect the first electrode 124 of the light-emitting element LED to the source electrode SE of the driving transistor DT. However, the present disclosure is not limited thereto. For example, the first connection electrode CE1 may be made of a transparent conductive material such as indium tin oxide (ITO) or indium zinc oxide (IZO). However, the present disclosure is not limited thereto.

In the first contact area CA1 and the second contact area CA2, the second connection electrode CE2 may be disposed on the first planarization layer 117a. The second connection electrode CE2 is an electrode that electrically connects the light-emitting element LED and the power line VDD. The second connection electrode CE2 may be connected to the second reflective electrode RE2 through contact holes formed in the first planarization layer 117a and the bonding layer 116. For example, the second connection electrode CE2 may be electrically connected to the second reflective electrode RE2 through a first contact hole CH1 of the bonding layer 116 disposed in the first contact area CA1 and a second contact hole CH2 of the first planarization layer 117a that overlaps the first contact hole CH1. Therefore, the second connection electrode CE2 may be electrically connected to the power line VDD through the second reflective electrode RE2. For example, the second connection electrode CE2 may connect the second electrode 125 of the light-emitting element LED and the power line VDD. However, the present disclosure is not limited thereto.

Meanwhile, the second connection electrode CE2 may be disposed on the same layer and made of the same material as the first connection electrode CE1. However, the present disclosure is not limited thereto. For example, the second connection electrode CE2 may be made of a transparent conductive material such as indium tin oxide (ITO) or indium zinc oxide (IZO). However, the present disclosure is not limited thereto.

The second passivation layer 114b may be disposed on the plurality of first connection electrodes CE1 and the plurality of second connection electrodes CE2. The second passivation layer 114b may be disposed on the plurality of first connection electrodes CE1 and the plurality of second connection electrodes CE2 and block the permeation of moisture or impurities into the plurality of reflective electrodes RE1 connected to the plurality of first connection electrodes CE1 and the plurality of second connection electrodes CE2. For example, the second passivation layer 114b may be configured as a single layer or multilayer made of silicon oxide (SiOₓ) or silicon nitride (SiNₓ). However, the present disclosure is not limited thereto.

In addition, the second passivation layer 114b may be disposed to cover at least a part of the first connection electrode CE1 so that the first connection electrode CE1 and the third connection electrode CE3 may be separated from each other. Therefore, the second passivation layer 114b may inhibit the first connection electrode CE1 and the third connection electrode CE3 from being short-circuited.

The second passivation layer 114b may include a first opening portion OP1 through which the first planarization layer 117a is exposed. For example, the first opening portion OP1 may be disposed between the first connection electrode CE1 and the second connection electrode CE2.

The second planarization layer 117b may be disposed on the second passivation layer 114b. The second planarization layer 117b, together with the first planarization layer 117a, may planarize the upper portion of the substrate 110 on which the light-emitting element LED is disposed. The second planarization layer 117b, together with the bonding layer 116, may fix the light-emitting element LED onto the substrate 110.

In addition, the second planarization layer 117b may be disposed to cover the first connection electrode CE1 so that the first connection electrode CE1 and the third connection electrode CE3 may be separated from each other. Therefore, it is possible to inhibit the first connection electrode CE1 and the third connection electrode CE3 from being short-circuited.

In particular, the second planarization layer 117b may be disposed to cover an end of the first connection electrode CE1 exposed by the second passivation layer 114b so that the first connection electrode CE1 and the third connection electrode CE3 may be separated from each other. For example, during the process of forming the second planarization layer 117b, a curing process may allow the second planarization layer 117b to flow downward, i.e., reflow onto the end of the first connection electrode CE1 exposed by the second passivation layer 114b. Therefore, a portion of the second planarization layer 117b, which overlaps the end of the first connection electrode CE1 exposed by the second passivation layer 114b, may be relatively low in height. In other words, a portion of the second planarization layer 117b, which surrounds the end of the first connection electrode CE1, may have an inclination.

For example, the end of the first connection electrode CE1, which contacts the light-emitting element LED, may be exposed by the second passivation layer 114b. Therefore, the height of the second planarization layer 117b may decrease toward the light-emitting element LED. However, because the second planarization layer 117b is disposed to cover the end of the first connection electrode CE1 exposed by the second passivation layer 114b, a height of a lowermost end of a top surface of the second planarization layer 117b may be higher than a height of an uppermost end of a top surface of the end of the first connection electrode CE1 exposed by the second passivation layer 114b.

Meanwhile, the second planarization layer 117b may be disposed in the first opening portion OP1 and cover the end of the first connection electrode CE1 and the end of the second connection electrode CE2, such that the first connection electrode CE1 and the second connection electrode CE2 may be separated from each other. Therefore, it is possible to inhibit the first connection electrode CE1 and the second connection electrode CE2 from being short-circuited.

Specifically, an opening portion, which overlaps the first opening portion OP1 of the second passivation layer 114b, may be formed in the second planarization layer 117b, and the curing process may allow the second planarization layer 117b to reflow in the first opening portion OP1. Therefore, a width of a second opening portion OP2, which is formed as the second planarization layer 117b reflows, may be smaller than a width of the first opening portion OP1. The details related to the above-mentioned configuration will be described below with reference to FIGS. 4A to 4H.

The second planarization layer 117b may be configured as a single layer or multilayer. For example, like the first planarization layer 117a, the second planarization layer 117b may be made of a photoresist or an acrylic-based organic material. However, the present disclosure is not limited thereto.

The third connection electrode CE3 may be disposed on the second planarization layer 117b. The third connection electrode CE3 is an electrode that electrically connects the light-emitting element LED and the power line VDD. The third connection electrode CE3 may be connected to the second reflective electrode RE2 through contact holes formed in the second planarization layer 117b, the second passivation layer 114b, the first planarization layer 117a, and the bonding layer 116. Therefore, the third connection electrode CE3 may be electrically connected to the power line VDD through the second reflective electrode RE2. For example, the third connection electrode CE3 may connect the second electrode 125 of the light-emitting element LED and the power line VDD. However, the present disclosure is not limited thereto. For example, the third connection electrode CE3 may be made of a transparent conductive material such as indium tin oxide (ITO) or indium zinc oxide (IZO). However, the present disclosure is not limited thereto.

For example, the third connection electrode CE3 may be disposed in the first contact hole CH1 of the bonding layer 116 disposed in the first contact area CA1, the second contact hole CH2 of the first planarization layer 117a, a third contact hole CH3 of the second passivation layer 114b, which overlaps the first contact hole CH1 and the second contact hole CH2, and a fourth contact hole CH4 of the second planarization layer 117b that overlaps the first contact hole CH1, the second contact hole CH2, and the third contact hole CH3. The third connection electrode CE3 may contact the second connection electrode CE2. Therefore, the third connection electrode CE3 may be electrically connected to the second reflective electrode RE2 through the second connection electrode CE2 and electrically connected to the power line VDD through the second reflective electrode RE2.

In this case, the third connection electrode CE3 may be additionally and electrically connected to the second connection electrode CE2 in the second contact area CA2. For example, the third connection electrode CE3 may be continuously disposed in the first contact area CA1 and the second contact area CA2 and electrically connected to the second connection electrode CE2, which extends from the first contact area CA1, through a fifth contact hole CH5 of the second passivation layer 114b disposed in the second contact area CA2 and a sixth contact hole CH6 of the second planarization layer 117b. That is, the third connection electrode CE3 may receive a power voltage from the power line VDD through the second connection electrode CE2 in the second contact area CA2 as well as the first contact area CA1. Therefore, it is possible to reduce resistance between the power line VDD and the third connection electrode CE3.

In particular, unlike the third contact hole CH3 and the fourth contact hole CH4 of the first contact area CA1, the fifth contact hole CH5 and the sixth contact hole CH6 of the second contact area CA2 may not overlap the first contact hole CH1 of the bonding layer 116 and the second contact hole CH2 of the first planarization layer 117a. Therefore, it is possible to improve the electrical connection between the third connection electrode CE3 and the second connection electrode CE2 by minimizing or reducing defects of the bonding layer 116 and the first planarization layer 117a caused by a residual film.

In addition, even though the second connection electrode CE2 and the third connection electrode CE3 are not electrically connected to each other in any one of the first contact area CA1 and the second contact area CA2, the second connection electrode CE2 and the third connection electrode CE3 may be connected in the remaining one area. Therefore, it is possible to improve the electrical connection between the second connection electrode CE2 and the third connection electrode CE3.

Meanwhile, the third connection electrode CE3 is disposed on the second electrode 125 and provided to be in direct contact with the second electrode 125, such that during an illumination inspection, an illumination inspection signal may be transmitted directly to the second electrode 125 without passing through the driving transistor DT. Therefore, it is not necessary to separately operate the driving transistor DT, such that a defect of the light-emitting element LED may be detected regardless of a defect of the driving transistor DT.

In addition, the third connection electrode CE3 may be formed before a process of forming the bank 118 to be described below. Therefore, a defect of the light-emitting element LED may be detected before the process of forming the bank 118.

Meanwhile, the third connection electrode CE3 may be disposed in the first opening portion OP1 and the second opening portion OP2 and provided to be in contact with the second planarization layer 117b. In this case, because a width of the second opening portion OP2 is smaller than a width of the first opening portion OP1, the third connection electrode CE3 may not be in contact with the second passivation layer 114b. However, the present disclosure is not limited thereto.

The illumination inspection pattern APP may be disposed on the second planarization layer 117b in the illumination inspection area APA. The illumination inspection pattern APP may contact the first connection electrode CE1 through a seventh contact hole CH7 formed in the second passivation layer 114b and an eighth contact hole CH8 formed in the second planarization layer 117b.

Therefore, the illumination inspection pattern APP may be electrically connected to the first electrode 124 of the light-emitting element LED through the first connection electrode CE1. Therefore, the illumination inspection signal may be transmitted directly to the first electrode 124 of the light-emitting element LED without passing through the driving transistor DT. Therefore, it is not necessary to separately operate the driving transistor DT, such that a defect of the light-emitting element LED may be detected regardless of a defect of the driving transistor DT. The illumination inspection pattern APP may be disposed on the same layer and made of the same material as the third connection electrode CE3. However, the present disclosure is not limited thereto. Therefore, like the third connection electrode CE3, the illumination inspection pattern APP is formed before the process of forming the bank 118 to be described below, such that a defect of the light-emitting element LED may be detected before the process of forming the bank 118. For example, the illumination inspection pattern APP may be made of a transparent conductive material or the like such as indium tin oxide (ITO) or indium zinc oxide (IZO). Therefore, the illumination inspection pattern APP may be referred to as a conductive pattern. However, the present disclosure is not limited thereto.

A protection pattern PP may be disposed on the second planarization layer 117b. The protection pattern PP may be disposed to cover the first reflective electrode RE1 exposed by the contact hole of the bonding layer 116. Therefore, the protection pattern PP may protect the first connection electrode RE1. For example, the protection pattern PP may serve as a mask during the process of ashing the second planarization layer 117b, such that the ashing process may suppress the oxidation of the first reflective electrode RE1.

In addition, the protection pattern PP may be connected to the first connection electrode RE1 and reduce line resistance of the first connection electrode RE1.

The bank 118 may be disposed on the second planarization layer 117b, the third connection electrode CE3, and the second illumination inspection pattern APP. Therefore, the bank 118 may be in direct contact with the second planarization layer 117b, the third connection electrode CE3, and the second illumination inspection pattern APP. However, the present disclosure is not limited thereto. The bank 118 may be disposed so as not to overlap the light-emitting element LED, and the bank 118 may define a light-emitting area. For example, the bank 118 may define the light-emitting area by covering the edge of the third connection electrode CE3 connected to the light-emitting element LED. That is, the bank 118 may separate the plurality of subpixels SP. The bank 118 may be made of an insulating material to insulate the second connection electrodes CE3 of the adjacent subpixels SP. In addition, the bank 118 may include a black component with a high optical absorption rate to suppress a color mixture between the adjacent subpixels SP, and the bank 118 may be configured as a black bank. For example, the bank 118 may be made of polyimide resin, acrylic resin, or benzocyclobutene (BCB) resin. However, the present disclosure is not limited thereto.

The third planarization layer 119 may be disposed on the second planarization layer 117b and the bank 118. The third planarization layer 119 may be disposed to cover a top surface of the light-emitting element LED and fix and protect the light-emitting element LED while simultaneously planarizing the upper portion of the substrate 110 on which the light-emitting element LED is disposed. Therefore, the third planarization layer 119 may be referred to as a protective layer or a capping layer. However, the present disclosure is not limited thereto. The third planarization layer 119 may be configured as a single layer or multilayer and made of a photoresist or an acrylic-based organic material, for example. However, the present disclosure is not limited thereto.

Hereinafter, a method of manufacturing the display device according to the embodiment of the present disclosure will be described with reference to FIGS. 4A to 4H.

FIGS. 4A to 4H are process diagrams of the method of manufacturing the display device according to an example embodiment of the present disclosure.

First, with reference to FIGS. 4A to 4H, the light-emitting element LED may be disposed on the bonding layer 116, and the first planarization layer 117a may be disposed on the bonding layer 116 and surround the light-emitting element LED.

A connection electrode material layer CE′ and a second-first passivation material layer 114b′ may be sequentially disposed on the front surface of the substrate 110 on the first planarization layer 117a and the light-emitting element LED.

The connection electrode material layer CE′ may be disposed on the front surface of the substrate 110 and cover the light-emitting element LED and the first planarization layer 117a. Therefore, the connection electrode material layer CE′ may also be disposed in the second contact hole CH2 formed in the first planarization layer 117a and the first contact hole CH1 of the bonding layer 116 that overlaps the second contact hole CH2. In addition, the connection electrode material layer CE′ may be disposed to cover both the side surface and the top surface of the light-emitting element LED.

The second-first passivation material layer 114b′ may be disposed on the front surface of the substrate 110 on the connection electrode material layer CE′. The second-first passivation material layer 114b′ may be disposed to be spaced apart from the light-emitting element LED, the first planarization layer 117a, and the bonding layer 116 by the connection electrode material layer CE′.

Meanwhile, the second-first passivation material layer 114b′ may be formed by a deposition process. In this case, a temperature of the deposition process for the second-first passivation material layer 114b′ may be determined in consideration of the connection electrode material layer CE′ disposed below the second-first passivation material layer 114b′. For example, in case that the connection electrode material layer CE′ is made of indium tin oxide (ITO) that is a transparent conductive material, the connection electrode material layer CE′ may be crystallized at about 250° C. To suppress the crystallization, the deposition process for the second-first passivation material layer 114b′ may be performed under a condition with a relatively low temperature of about 200° C. or less, e.g., about 180° C.

Next, with reference to FIG. 4B, a second-first planarization material layer 117b′ may be disposed on the second-first passivation material layer 114b′ and surround the light-emitting element LED. A height of the second-first planarization material layer 117b′ may be lower than a height of the second electrode 125 of the light-emitting element LED. For example, a thickness of the second-first planarization material layer 117b′ may be adjusted by performing an ashing process. For example, after the second-first planarization material layer 117b′ is applied to cover the light-emitting element LED, the ashing process is performed to decrease an overall thickness of the second-first planarization material layer 117b′, such that a height of the second-first planarization material layer 117b′ may be lower than a height of the second electrode 125. Therefore, during a subsequent process, the third connection electrode CE3 disposed on the second-first planarization material layer 117b′ may be easily connected to the second electrode 125.

Meanwhile, an initial second opening portion OP2′ may be formed in the second-first planarization material layer 117b′. The initial second opening portion OP2′ may expose the second-first passivation material layer 114b′.

Next, with reference to FIG. 4C, a second-second passivation material layer 114b″ may be formed by etching the second-first passivation material layer 114b′. The second-second passivation material layer 114b″ may be formed by etching the second-first passivation material layer 114b′ exposed from the second-first planarization material layer 117b′.

For example, because the second-first planarization material layer 117b′ is formed to have a thickness smaller than a thickness of the light-emitting element LED, the second-first passivation material layer 114b′, which covers an upper side of the light-emitting element LED, may be exposed from the second-first planarization material layer 117b′.

In addition, because the second-first planarization material layer 117b′ is opened in the initial second opening portion OP2′, the second-first passivation material layer 114b′, which overlaps the initial second opening portion OP2′, may be exposed from the second-first planarization material layer 117b′. Therefore, the second-second passivation material layer 114b″ may be formed by etching a portion of the second-first passivation material layer 114b′, which covers the upper side of the light-emitting element LED, and a portion of the second-first passivation material layer 114b′ that overlaps the initial second opening portion OP2′. Therefore, the first opening portion OP1, which overlaps the initial second opening portion OP2′, may be formed in the second-second passivation material layer 114b″.

For example, the second-second passivation material layer 114b″ may be formed by a wet etching process. Therefore, not only the portion of the second-first passivation material layer 114b′, which is exposed by the second-first planarization material layer 117b′, but also the portion of the second-first passivation material layer 114b′, which overlaps the second-first planarization material layer 117b′, may be partially removed. Therefore, an end of the second-second passivation material layer 114b″ may be disposed inward of an end of the second-first planarization material layer 117b′. Therefore, a width of the first opening portion OP1 may be larger than a width of the initial second opening portion OP2′. However, the present disclosure is not limited thereto.

Meanwhile, a second-second planarization material layer 117b″ may be formed by etching a part of the second-first planarization material layer 117b′ during the process of etching the second-second passivation material layer 114b″. For example, a part of a portion of the second-first planarization material layer 117b′, which is adjacent to the light-emitting element LED, may also be etched. However, the present disclosure is not limited thereto.

Next, with reference to FIG. 4D, the first connection electrode CE1, the second connection electrode CE2, and the protection pattern PP may be formed by etching the connection electrode material layer CE′. The first connection electrode CE1, the second connection electrode CE2, and the protection pattern PP may be formed by etching the connection electrode material layer CE′ exposed from the second-first planarization material layer 117b″ and the second-second passivation material layer 114b″.

Specifically, the second-second planarization material layer 117b″ is opened in the initial second opening portion OP2′, and the second-second passivation material layer 114b″ is opened in the first opening portion OP1, such that the connection electrode material layer CE′, which overlaps the initial second opening portion OP2′ and the first opening portion OP1, may be exposed from the second-second planarization material layer 117b″ and the second-second passivation material layer 114b″. Therefore, the first connection electrode CE1, the second connection electrode CE2, and the protection pattern PP may be formed by etching a portion of the connection electrode material layer CE′ that overlaps the initial second opening portion OP2′ and the first opening portion OP1.

For example, the first connection electrode CE1, the second connection electrode CE2, and the protection pattern PP may be formed by a wet etching process. Therefore, not only the portion of the connection electrode material layer CE′, which is exposed by the second-second planarization material layer 117b″ and the second-second passivation material layer 114b″, but also the portion of the connection electrode material layer CE′, which overlaps the second-second planarization material layer 117b″ and the second-second passivation material layer 114b″, may be partially removed. Therefore, the end of the first connection electrode CE1, the end of the second connection electrode CE2, and the end of the protection pattern PP may be disposed inward of the end of the second-second planarization material layer 117b″ and the end of the second-second passivation material layer 114b″. However, the present disclosure is not limited thereto.

Meanwhile, a second-third passivation layer 114b″′ may also be formed by etching a part of the second-second passivation material layer 114b″. For example, not only the connection electrode material layer CE′, which is disposed on the side surface of the light-emitting element LED, but also the second-second passivation material layer 114b″ may be exposed by the second-second planarization material layer 117b″. Therefore, the second-third passivation layer 114b″′ may be formed by removing a part of the second-second passivation material layer 114b″ disposed on the side surface of the light-emitting element LED.

Meanwhile, a part of the second-second passivation material layer 114b″ adjacent to the light-emitting element LED is removed, such that the end of the first connection electrode CE1, which contacts the light-emitting element LED, may be exposed by the second-third passivation layer 114b″′. However, the present disclosure is not limited thereto.

Next, with reference to FIG. 4E, a second-third planarization material layer 117b″′ may be formed by partially ashing, e.g., halftone-ashing the second-second planarization material layer 117b″.

For example, a portion of the second-second planarization material layer 117b″, which overlaps the second connection electrode CE2, may be partially ashed. For example, an initial fourth contact hole CH4′ may be formed by ashing a portion of the second-second planarization material layer 117b″ that overlaps the first contact hole CH1 and the second contact hole CH2. Therefore, the initial fourth contact hole CH4′ may overlap the first contact hole CH1 and the second contact hole CH2. The initial fourth contact hole CH4′ may be disposed on the second connection electrode CE2 so that the third connection electrode CE3 and the second connection electrode CE2 are connected during a subsequent process.

In addition, an initial sixth contact hole CH6′ may be formed by ashing a portion of the second-second planarization material layer 117b″ that overlaps the second connection electrode CE2 but does not overlap the first contact hole CH1 and the second contact hole CH2. The initial sixth contact hole CH6′ may be disposed on the second connection electrode CE2 so that the third connection electrode CE3 and the second connection electrode CE2 are additionally connected during a subsequent process.

In addition, an initial eighth contact hole CH8′ may be formed by partially ashing a portion of the second-second planarization material layer 117b″ that overlaps the first connection electrode CE1. The initial eighth contact hole CH8′ may allow the illumination inspection pattern APP and the first connection electrode CE1 to be connected during a subsequent process.

Next, with reference to FIG. 4F, the second passivation layer 114b may be formed by etching the second-third passivation material layer 114b″′. The second passivation layer 114b may be formed by etching the second-third passivation material layer 114b″′ exposed from the second-third planarization material layer 117b″′.

For example, because the second-third planarization material layer 117b″′ is opened in the initial fourth contact hole CH4′, the initial sixth contact hole CH6', and the initial eighth contact hole CH8′, the second-third passivation material layer 114b″′, which overlaps the initial fourth contact hole CH4′, the initial sixth contact hole CH6', and the initial eighth contact hole CH8′, may be exposed from the second-third planarization material layer 117b″′. Therefore, the second passivation layer 114b may be formed by etching the second-third passivation material layer 114b″′ exposed by the initial fourth contact hole CH4′, the initial sixth contact hole CH6′, and the initial eighth contact hole CH8′. Therefore, the third contact hole CH3, which overlaps the initial fourth contact hole CH4′, the fifth contact hole CH5, which overlaps the initial sixth contact hole CH6′, and the seventh contact hole CH7, which overlaps the initial eighth contact hole CH8′, may be formed in the second passivation layer 114b.

For example, the second passivation layer 114b may be formed by a dry etching process. Therefore, unlike the wet etching process, the portion of the second-third passivation material layer 114b″′, which overlaps the second-third planarization material layer 117b″′, may not be removed, but only the portion of the second-third passivation material layer 114b″′ exposed by the second-third planarization material layer 117b″′ may be removed. Therefore, an end of a portion of the second passivation layer 114b, which is opened by the third contact hole CH3, the fifth contact hole CH5, and the seventh contact hole CH7, may be consistent with an end of a portion of the second-third planarization material layer 117b″′ opened by the initial fourth contact hole CH4′, the initial sixth contact hole CH6′, and the initial eighth contact hole CH8′. However, the present disclosure is not limited thereto.

Next, with reference to FIG. 4G, the second planarization layer 117b may be formed by curing the second-third planarization material layer 117b″′. Specifically, the curing process may allow the second-third planarization material layer 117b″′ to reflow, such that the second-third planarization material layer 117b″′ may cover the end of the second passivation layer 114b disposed below the second-third planarization material layer.

Specifically, the second-third planarization material layer 117b″′ opened by the initial fourth contact hole CH4′ may reflow and be disposed in the third contact hole CH3. Therefore, the second planarization layer 117b may be disposed to cover an end of the second passivation layer 114b opened by the third contact hole CH3. Therefore, a width of the fourth contact hole CH4 may be smaller than a width of the third contact hole CH3.

The second-third planarization material layer 117b″′ opened by the initial sixth contact hole CH6′ may reflow and be disposed in the fifth contact hole CH5. Therefore, the second planarization layer 117b may be disposed to cover an end of the second passivation layer 114b opened by the fifth contact hole CH5. Therefore, a width of the sixth contact hole CH6 may be smaller than a width of the fifth contact hole CH5.

The second-third planarization material layer 117b″′ opened by the initial eighth contact hole CH8′ may reflow and be disposed in the seventh contact hole CH7. Therefore, the second planarization layer 117b may be disposed to cover an end of the second passivation layer 114b opened by the seventh contact hole CH7. Therefore, a width of the eighth contact hole CH8 of the second planarization layer 117b may be smaller than a width of the seventh contact hole CH7.

The second-third planarization material layer 117b″′ opened by an initial second opening portion OP2′ may reflow and be disposed in the first opening portion OP1. Therefore, the second planarization layer 117b may be disposed to cover an end of the second passivation layer 114b opened by the first opening portion OP1. Therefore, a width of the second opening portion OP2 of the second planarization layer 117b may be smaller than a width of the first opening portion OP1.

Meanwhile, the second planarization layer 117b may reflow to the first opening portion OP1 and be disposed on the first planarization layer 117a that overlaps the first opening portion OP1. In this case, because the first opening portion OP1 is disposed between the first connection electrode CE1 and the second connection electrode CE2, the second planarization layer 117b may be disposed to cover the end of the first connection electrode CE1 and the end of the second connection electrode CE2. Therefore, the second planarization layer 117b may allow the first connection electrode CE1 and the second connection electrode CE2 to be separated.

In particular, the second planarization layer 117b may be disposed to cover not only the end of the second passivation layer 114b but also the end of the first connection electrode CE1 exposed by the second passivation layer 114b. Therefore, the second planarization layer 117b may allow the first connection electrode CE1 and the third connection electrode CE3 to be separated from each other during a subsequent process.

Specifically, as described above, the end of the first connection electrode CE1, which contacts the light-emitting element LED, may be exposed by the second passivation layer 114b. In this case, the curing process may allow the second planarization layer 117b to reflow, such that the second planarization layer 117b may be disposed on the end of the first connection electrode CE1 exposed by the second passivation layer 114b. Therefore, the second planarization layer 117b may reflow and cover the end of the first connection electrode CE1 that contacts the light-emitting element LED. Therefore, a height of the second planarization layer 117b may decrease toward the light-emitting element LED. The second planarization layer 117b may be disposed to cover the end of the first connection electrode CE1 and the end of the second passivation layer 114b disposed to surround a part of the side surface of the light-emitting element LED. An inclination direction of the end of the first connection electrode CE1 of the side surface of the light-emitting element LED and the end of the second passivation layer 114b may be identical to an inclination direction of the second planarization layer 117b that covers the end of the first connection electrode CE1 and the end of the second passivation layer 114b. The second planarization layer 117b and the light-emitting element LED may define a ‘V’ shape at a portion where the second planarization layer 117b contacts the side surface of the light-emitting element LED. As shown in FIG. 3 and FIG. 4H, the side surface of the light-emitting element LED might be a left surface of the light-emitting element LED, a right surface of the light-emitting element LED or both of the left surface and the right surface of the light-emitting element LED.

Next, with reference to FIG. 4H, the third connection electrode CE3 and the illumination inspection pattern APP may be disposed on the second planarization layer 117b and spaced apart from each other. The third connection electrode CE3 may be disposed on the light-emitting element LED, and the illumination inspection pattern APP may be disposed to overlap the eighth contact hole CH8.

As described above, the second planarization layer 117b is formed by performing the ashing process only until the second electrode 125 of the light-emitting element LED is exposed. The third connection electrode CE3 disposed on the second planarization layer 117b may contact only the top surface of the second electrode 125 exposed from the second planarization layer 117b, and the third connection electrode CE3 may be spaced apart from the first connection electrode CE1, the light-emitting layer 122, and the first semiconductor layer 121 disposed below the second planarization layer 117b. Therefore, the third connection electrode CE3 and the second electrode 125 may be self-aligned without having to ensure a process margin.

Meanwhile, the illumination inspection pattern APP may be disposed in the seventh contact hole CH7 and the eighth contact hole CH8 on the second planarization layer 117b and electrically connected to the first connection electrode CE1 exposed by the seventh contact hole CH7 and the eighth contact hole CH8.

In this case, the illumination inspection may be performed. For example, the illumination inspection signals may be applied to the illumination inspection pattern APP and the third connection electrode CE3. Therefore, the illumination inspection signal applied through the illumination inspection pattern APP may be transmitted to the first electrode 124 of the light-emitting element LED through the first connection electrode CE1. The illumination inspection signals applied through the third connection electrode CE3 may be transmitted to the second electrode 125 of the light-emitting element LED. Therefore, it is possible to detect whether the light-emitting element LED is defective regardless of whether the driving transistor DT is defective.

Next, the bank 118 and the third planarization layer 119 are disposed on the second planarization layer 117b, the third connection electrode CE3, and the illumination inspection pattern APP, such that the process of manufacturing the display device 100 may be completed.

During a process of disposing or transferring the plurality of light-emitting elements onto the substrate, some of the light-emitting elements may be misaligned or erroneously disposed. In this case, in case that a subsequent process is performed in the state in which some of the light-emitting elements are misaligned or erroneously disposed, a short-circuit defect between the electrodes may occur. For example, in case that the light-emitting elements are misaligned and the same electrode is connected to the first electrode and the second electrode of the light-emitting element or in case that the electrodes respectively connected to the first electrode and the second electrode of the light-emitting element disposed to overlap each other without being disposed to be separated, a short-circuit defect occurs, and the light-emitting element may not normally emit light.

Therefore, in the display device 100 according to the embodiment of the present disclosure, the first connection electrode CE1 and the first electrode 124 of the light-emitting element LED may be self-aligned and connected. For example, after the material layer of the first planarization layer 117a is applied to cover the light-emitting element LED, the material layer of the first planarization layer 117a is ashed, such that the first electrode 124 may be exposed. Therefore, the first connection electrode CE1 disposed on the first planarization layer 117a may be easily connected to the first electrode 124 without a separate contact hole. Therefore, the first connection electrode CE1 and the first electrode 124 may be self-aligned without having to ensure a process margin. Therefore, it is possible to minimize or reduce short-circuit defects of the first connection electrode CE1 and the third connection electrode CE3 caused by a process error.

Likewise, in the display device 100 according to the embodiment of the present disclosure, the third connection electrode CE3 and the second electrode 125 of the light-emitting element LED may be self-aligned and connected. For example, after the material layer of the second planarization layer 117b is applied to cover the second semiconductor layer 123 and the second electrode 125 of the light-emitting element LED, the material layer of the second planarization layer 117b is ashed, such that only the second electrode 125 may be exposed. Therefore, even though the second connection electrode CE2 is formed by forming and patterning the material layer of the second connection electrode CE2 on the front surface of the substrate 110 including the second planarization layer 117b, the second connection electrode CE2 may contact only the top surface of the second electrode 125 exposed from the second planarization layer 117b. That is, the third connection electrode CE3 and the second electrode 125 may be self-aligned without having to ensure a process margin. Therefore, it is possible to minimize or reduce short-circuit defects of the first connection electrode CE1 and the third connection electrode CE3 caused by a process error.

In addition, in the display device 100 according to the embodiment of the present disclosure, the second passivation layer 114b may be disposed on the first connection electrode CE1 and the second connection electrode CE2. Because the second passivation layer 114b is disposed to cover at least a part of the first connection electrode CE1, the second passivation layer 114b, together with the second planarization layer 117b, may allow the first connection electrode CE1 and the third connection electrode CE3 to be separated from each other. Therefore, the second passivation layer 114b may inhibit the first connection electrode CE1 and the third connection electrode CE3 from being short-circuited.

Furthermore, the second passivation layer 114b is made of an inorganic insulating material, which may suppress the permeation of moisture or impurities into the plurality of reflective electrodes RE connected to the plurality of first connection electrodes CE1 and the plurality of second connection electrodes CE2. Therefore, it is possible to suppress separation and corrosion of the plurality of reflective electrodes RE caused by moisture permeation.

In particular, in the display device 100 according to the embodiment of the present disclosure, in case that the first connection electrode CE1 is exposed by the second passivation layer 114b, the second planarization layer 117b reflows onto the exposed first connection electrode CE1, such that the first connection electrode CE1 and the third connection electrode CE3 may be separated. For example, the curing process allows the second planarization layer 117b to reflow, such that the second planarization layer 117b may be disposed to cover the first connection electrode CE1 exposed by the second passivation layer 114b. Therefore, in the display device 100 according to the embodiment of the present disclosure, even though the first connection electrode CE1 is exposed by the second passivation layer 114b during the process, the second planarization layer 117b may reflow, such that the first connection electrode CE1 and the third connection electrode CE3 may be separated, which may suppress a short-circuit defect in which the first connection electrode CE1 and the third connection electrode CE3 are connected.

Various example embodiments of the present disclosure can also be described as follows:
According to an aspect of the present disclosure, there is provided a display device. The display device includes a substrate on which a plurality of subpixels is defined, power line and a driving transistor disposed on the substrate, a first reflective electrode and a second reflective electrode disposed on the power line and the driving transistor and spaced apart from each other, the first reflective electrode being connected to the driving transistor, and the second reflective electrode being connected to the power line, a bonding layer disposed on the first reflective electrode and the second reflective electrode, a plurality of light-emitting elements respectively disposed in the plurality of subpixels on the bonding layer and including a first electrode and a second electrode, a first planarization layer disposed on the bonding layer and configured to partially surround side surfaces of the plurality of light-emitting elements, a first connection electrode disposed on the first planarization layer and configured to connect the first electrode and the driving transistor, a second connection electrode disposed on the first planarization layer, spaced apart from the first connection electrode, and connected to the second reflective electrode, a passivation layer disposed on the first connection electrode and the second connection electrode, a second planarization layer disposed on the passivation layer and configured to partially surround the side surfaces of the plurality of light-emitting elements and a third connection electrode disposed on the second planarization layer and configured to connect the second electrode and the power line. The passivation layer exposes an end of the first connection electrode disposed to surround a part of a side surface of a light-emitting element, among the plurality of light-emitting elements. The second planarization layer covers the end of the first connection electrode.

The second planarization layer may be disposed to cover the end of the first connection electrode and an end of the passivation layer corresponding to the end of the first connection electrode.

An inclination direction of the end of the first connection electrode and the end of the passivation layer disposed on the side surface of the light-emitting element may be identical to an inclination direction of the second planarization layer that covers the end of the first connection electrode and the end of the passivation layer. The second planarization layer may define a ‘V’ shape in an area that contacts the light-emitting element.

A height of a portion of the second planarization layer, which overlaps the end of the first connection electrode, may be lower than a height of a portion of the second planarization layer that does not overlap the end of the first connection electrode.

The passivation layer may include a first opening portion that exposes the first planarization layer. The second planarization layer may include a second opening portion that overlaps the first opening portion. A width of the first opening portion may be larger than a width of the second opening portion. The second planarization layer may be disposed in the first opening portion and may cover another end of the first connection electrode and an end of the second connection electrode.

The third connection electrode may be disposed in the first opening portion and the second opening portion and provided to be in contact with the first planarization layer.

The bonding layer may include a first contact hole that exposes the second reflective electrode. The first planarization layer may include a second contact hole that overlaps the first contact hole and exposes the second reflective electrode. The second connection electrode may be disposed in the first contact hole and the second contact hole and may contact the second reflective electrode. The passivation layer may include a third contact hole that overlaps the first contact hole and the second contact hole and exposes the second connection electrode. The second planarization layer may include a fourth contact hole that overlaps the first contact hole, the second contact hole, and the third contact hole and exposes the second connection electrode. The third connection electrode may be disposed in the first contact hole, the second contact hole, the third contact hole, and the fourth contact hole and may contact the second connection electrode.

A width of the third contact hole may be larger than a width of the fourth contact hole. The second planarization layer may be disposed in the third contact hole and may cover an end of the passivation layer.

The bonding layer may include a first contact hole that exposes the second reflective electrode. The first planarization layer may include a second contact hole that overlaps the first contact hole and exposes the second reflective electrode. The second connection electrode may be disposed in the first contact hole and the second contact hole and may contact the second reflective electrode. The passivation layer may include a fifth contact hole that exposes the second connection electrode without overlapping the first contact hole and the second contact hole. The second planarization layer may include a sixth contact hole that overlaps the fifth contact hole. The third connection electrode may be disposed in the fifth contact hole and the sixth contact hole and may contact the second connection electrode.

A width of the fifth contact hole may be larger than a width of the sixth contact hole. The second planarization layer may be disposed in the fifth contact hole and may cover an end of the passivation layer.

The display device may further include a conductive pattern disposed on the second planarization layer. The passivation layer may include a seventh contact hole that exposes the first connection electrode. The second planarization layer may include an eighth contact hole that overlaps the seventh contact hole. The conductive pattern may be connected to the first connection electrode through the seventh contact hole and the eighth contact hole.

A width of the seventh contact hole may be larger than a width of the eighth contact hole. The second planarization layer may be disposed in the seventh contact hole and may cover an end of the passivation layer.

A height of the first planarization layer may be lower than a height of the first electrode, and a height of the second planarization layer is lower than a height of the second electrode.

The side surfaces of the plurality of light-emitting elements may be any one or both of two side surfaces of the plurality of light-emitting elements.

According to another aspect of the present disclosure, there is provided a display device. The display device includes a substrate on which a plurality of pixels each including a plurality of subpixels are defined, a power line and a driving transistor disposed on the substrate, a first reflective electrode and a second reflective electrode disposed on the power line and the driving transistor and spaced apart from each other, the first reflective electrode being connected to the driving transistor, and the second reflective electrode being connected to the power line, a bonding layer disposed on the first reflective electrode and the second reflective electrode, a plurality of light-emitting elements respectively disposed in the plurality of subpixels on the bonding layer and including a first electrode and a second electrode, a first planarization layer disposed on the bonding layer and configured to partially surround side surfaces of the plurality of light-emitting elements, a first connection electrode disposed on the first planarization layer and configured to connect the first electrode and the driving transistor, a second connection electrode disposed on the first planarization layer, spaced apart from the first connection electrode, and connected to the second reflective electrode, a passivation layer disposed on the first connection electrode and the second connection electrode, a second planarization layer disposed on the passivation layer and having a height that decreases toward the plurality of light-emitting elements and a third connection electrode disposed on the second planarization layer and configured to connect the second electrode and the power line.

The passivation layer may surround the plurality of light-emitting elements and may expose a part of the first connection electrode. A height of a lowermost end of a top surface of the second planarization layer may be higher than a height of an uppermost end of a top surface of the exposed part of the first connection electrode.

The passivation layer may include an opening portion that exposes the first planarization layer. The second planarization layer may include an opening portion that overlaps the opening portion of the passivation layer and may have a smaller width than the opening portion of the passivation layer. The second planarization layer may be disposed in the opening portion of the passivation layer and may separate the first connection electrode and the second connection electrode.

The plurality of pixels each may include a first area in which the third connection electrode and the power line may be electrically connected, and a second area adjacent to the first area. The third connection electrode in the first area may be connected to the power line through the second reflective electrode and the second connection electrode. The third connection electrode in the second area may be connected to the power line through the second connection electrode extending from the first area.

The bonding layer may include a contact hole that is disposed in the first area and exposes the second reflective electrode. The first planarization layer may include a contact hole that is disposed in the first area and overlaps the contact hole of the bonding layer. The second connection electrode may be connected to the second reflective electrode through the contact hole of the first planarization layer and the contact hole of the bonding layer.

The passivation layer may include a contact hole that is disposed in the first area, overlaps the contact hole of the first planarization layer and the contact hole of the bonding layer, and exposes the second connection electrode. The second planarization layer may include a contact hole that is disposed in the first area, overlaps the contact hole of the first planarization layer, the contact hole of the bonding layer, and the contact hole of the passivation layer, and exposes the second connection electrode. The third connection electrode may be connected to the second connection electrode through the contact hole of the second planarization layer, the contact hole of the passivation layer, the contact hole of the first planarization layer, and the contact hole of the bonding layer.

The passivation layer may further include a contact hole that is disposed in the second area and exposes the second connection electrode extending from the first area. The second planarization layer may further include a contact hole that is disposed in the second area and exposes the second connection electrode extending from the first area. The third connection electrode may be connected to the second connection electrode through the contact hole of the passivation layer disposed in the second area and the contact hole of the second planarization layer.

The display device may further an illumination inspection area disposed in each of the plurality of pixels, an illumination inspection pattern disposed on the second planarization layer in the illumination inspection area. The passivation layer may include a contact hole that is disposed in the illumination inspection area and exposes the first connection electrode. The second planarization layer may include a contact hole that overlaps the contact hole of the passivation layer and exposes the first connection electrode. The illumination inspection pattern may be connected to the first connection electrode through the contact hole of the second planarization layer and the contact hole of the passivation layer.

The passivation layer and the first connection electrode may also have heights that decrease toward the plurality of light-emitting elements.

The side surfaces of the plurality of light-emitting elements may be any one or both of two side surfaces of the plurality of light-emitting elements.

Although the above example embodiments of the present disclosure have been described in detail with reference to the accompanying drawings, the present disclosure is not limited thereto and may be embodied in many different forms without departing from the technical concept of the present disclosure. Therefore, the above example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate on which a plurality of subpixels is defined;
a power line and a driving transistor disposed on the substrate;
a first reflective electrode and a second reflective electrode disposed on the power line and the driving transistor and spaced apart from each other, the first reflective electrode being connected to the driving transistor, and the second reflective electrode being connected to the power line;
a bonding layer disposed on the first reflective electrode and the second reflective electrode;
a plurality of light-emitting elements respectively disposed in the plurality of subpixels on the bonding layer and including a first electrode and a second electrode;
a first planarization layer disposed on the bonding layer and configured to partially surround side surfaces of the plurality of light-emitting elements;
a first connection electrode disposed on the first planarization layer and configured to connect the first electrode and the driving transistor;
a second connection electrode disposed on the first planarization layer, spaced apart from the first connection electrode, and connected to the second reflective electrode;
a passivation layer disposed on the first connection electrode and the second connection electrode;
a second planarization layer disposed on the passivation layer and configured to partially surround the side surfaces of the plurality of light-emitting elements; and
a third connection electrode disposed on the second planarization layer and configured to connect the second electrode and the power line,
wherein the passivation layer exposes an end of the first connection electrode disposed to surround a part of a side surface of a light-emitting element, among the plurality of light-emitting elements, and
wherein the second planarization layer covers the end of the first connection electrode.

2. The display device of claim 1, wherein the second planarization layer is disposed to cover the end of the first connection electrode and an end of the passivation layer corresponding to the end of the first connection electrode.

3. The display device of claim 2, wherein an inclination direction of the end of the first connection electrode and the end of the passivation layer disposed on the side surface of the light-emitting element is identical to an inclination direction of the second planarization layer that covers the end of the first connection electrode and the end of the passivation layer, and
wherein the second planarization layer defines a ‘V’ shape in an area that contacts the light-emitting element.

4. The display device of claim 1, wherein a height of a portion of the second planarization layer, which overlaps the end of the first connection electrode, is lower than a height of a portion of the second planarization layer that does not overlap the end of the first connection electrode.

5. The display device of claim 1, wherein the passivation layer includes a first opening portion that exposes the first planarization layer,
wherein the second planarization layer includes a second opening portion that overlaps the first opening portion,
wherein a width of the first opening portion is larger than a width of the second opening portion, and
wherein the second planarization layer is disposed in the first opening portion and covers another end of the first connection electrode and an end of the second connection electrode.

6. The display device of claim 5, wherein the third connection electrode is disposed in the first opening portion and the second opening portion and provided to be in contact with the first planarization layer.

7. The display device of claim 1, wherein the bonding layer includes a first contact hole that exposes the second reflective electrode,
wherein the first planarization layer includes a second contact hole that overlaps the first contact hole and exposes the second reflective electrode,
wherein the second connection electrode is disposed in the first contact hole and the second contact hole and contacts the second reflective electrode,
wherein the passivation layer includes a third contact hole that overlaps the first contact hole and the second contact hole and exposes the second connection electrode,
wherein the second planarization layer includes a fourth contact hole that overlaps the first contact hole, the second contact hole, and the third contact hole and exposes the second connection electrode, and
wherein the third connection electrode is disposed in the first contact hole, the second contact hole, the third contact hole, and the fourth contact hole and contacts the second connection electrode.

8. The display device of claim 7, wherein a width of the third contact hole is larger than a width of the fourth contact hole, and
wherein the second planarization layer is disposed in the third contact hole and covers an end of the passivation layer.

9. The display device of claim 1, wherein the bonding layer includes a first contact hole that exposes the second reflective electrode,
wherein the first planarization layer includes a second contact hole that overlaps the first contact hole and exposes the second reflective electrode,
wherein the second connection electrode is disposed in the first contact hole and the second contact hole and contacts the second reflective electrode,
wherein the passivation layer includes a fifth contact hole that exposes the second connection electrode without overlapping the first contact hole and the second contact hole,
wherein the second planarization layer includes a sixth contact hole that overlaps the fifth contact hole, and
wherein the third connection electrode is disposed in the fifth contact hole and the sixth contact hole and contacts the second connection electrode.

10. The display device of claim 9, wherein a width of the fifth contact hole is larger than a width of the sixth contact hole, and
wherein the second planarization layer is disposed in the fifth contact hole and covers an end of the passivation layer.

11. The display device of claim 1, further comprising:
a conductive pattern disposed on the second planarization layer,
wherein the passivation layer includes a seventh contact hole that exposes the first connection electrode,
wherein the second planarization layer includes an eighth contact hole that overlaps the seventh contact hole, and
wherein the conductive pattern is connected to the first connection electrode through the seventh contact hole and the eighth contact hole.

12. The display device of claim 11, wherein a width of the seventh contact hole is larger than a width of the eighth contact hole, and
wherein the second planarization layer is disposed in the seventh contact hole and covers an end of the passivation layer.

13. The display device of claim 1, wherein a height of the first planarization layer is lower than a height of the first electrode, and a height of the second planarization layer is lower than a height of the second electrode.

14. The display device of claim 1, wherein the side surfaces of the plurality of light-emitting elements are any one or both of two side surfaces of the plurality of light-emitting elements.

15. A display device, comprising:
a substrate on which a plurality of pixels each including a plurality of subpixels are defined;
a power line and a driving transistor disposed on the substrate;
a first reflective electrode and a second reflective electrode disposed on the power line and the driving transistor and spaced apart from each other, the first reflective electrode being connected to the driving transistor, and the second reflective electrode being connected to the power line;
a bonding layer disposed on the first reflective electrode and the second reflective electrode;
a plurality of light-emitting elements respectively disposed in the plurality of subpixels on the bonding layer and including a first electrode and a second electrode;
a first planarization layer disposed on the bonding layer and configured to partially surround side surfaces of the plurality of light-emitting elements;
a first connection electrode disposed on the first planarization layer and configured to connect the first electrode and the driving transistor;
a second connection electrode disposed on the first planarization layer, spaced apart from the first connection electrode, and connected to the second reflective electrode;
a passivation layer disposed on the first connection electrode and the second connection electrode;
a second planarization layer disposed on the passivation layer and having a height that decreases toward the plurality of light-emitting elements; and
a third connection electrode disposed on the second planarization layer and configured to connect the second electrode and the power line.

16. The display device of claim 15, wherein the passivation layer surrounds the plurality of light-emitting elements and exposes a part of the first connection electrode, and
wherein a height of a lowermost end of a top surface of the second planarization layer is higher than a height of an uppermost end of a top surface of the exposed part of the first connection electrode.

17. The display device of claim 15, wherein the passivation layer includes an opening portion that exposes the first planarization layer,
wherein the second planarization layer includes an opening portion that overlaps the opening portion of the passivation layer and has a smaller width than the opening portion of the passivation layer, and
wherein the second planarization layer is disposed in the opening portion of the passivation layer and separates the first connection electrode and the second connection electrode.

18. The display device of claim 15, wherein the plurality of pixels each includes a first area in which the third connection electrode and the power line are electrically connected, and a second area spaced apart from the first area,
wherein in the first area, the third connection electrode is connected to the power line through the second reflective electrode and the second connection electrode, and
wherein in the second area, the third connection electrode is connected to the power line through the second connection electrode extending from the first area.

19. The display device of claim 18, wherein the bonding layer includes a contact hole that is disposed in the first area and exposes the second reflective electrode,
wherein the first planarization layer includes a contact hole that is disposed in the first area and overlaps the contact hole of the bonding layer, and
wherein the second connection electrode is connected to the second reflective electrode through the contact hole of the first planarization layer and the contact hole of the bonding layer.

20. The display device of claim 19, wherein the passivation layer includes a contact hole that is disposed in the first area, overlaps the contact hole of the first planarization layer and the contact hole of the bonding layer, and exposes the second connection electrode,
wherein the second planarization layer includes a contact hole that is disposed in the first area, overlaps the contact hole of the first planarization layer, the contact hole of the bonding layer, and the contact hole of the passivation layer, and exposes the second connection electrode, and
wherein the third connection electrode is connected to the second connection electrode through the contact hole of the second planarization layer, the contact hole of the passivation layer, the contact hole of the first planarization layer, and the contact hole of the bonding layer.

21. The display device of claim 19, wherein the passivation layer further includes a contact hole that is disposed in the second area and exposes the second connection electrode extending from the first area,
wherein the second planarization layer further includes a contact hole that is disposed in the second area and exposes the second connection electrode extending from the first area, and
wherein the third connection electrode is connected to the second connection electrode through the contact hole of the passivation layer disposed in the second area and the contact hole of the second planarization layer.

22. The display device of claim 15, further comprising:
an illumination inspection area disposed in each of the plurality of pixels, an illumination inspection pattern disposed on the second planarization layer in the illumination inspection area,
wherein the passivation layer includes a contact hole that is disposed in the illumination inspection area and exposes the first connection electrode,
wherein the second planarization layer includes a contact hole that overlaps the contact hole of the passivation layer and exposes the first connection electrode, and
wherein the illumination inspection pattern is connected to the first connection electrode through the contact hole of the second planarization layer and the contact hole of the passivation layer.

23. The display device of claim 15, wherein the passivation layer and the first connection electrode also have heights that decrease toward the plurality of light-emitting elements.

24. The display device of claim 15, wherein the side surfaces of the plurality of light-emitting elements are any one or both of two side surfaces of the plurality of light-emitting elements.
